(19) United States
(12) Patent Application Publication
(10) Pub. No.: US 2018/0308728 A1
(43) Pub. Date: Oct. 25, 2018

(54) METHOD AND APPARATUS FOR SUBSTRATE TRANSPORT

(71) Applicant: Brooks Automation, Inc., Chelmsford, MA (US)

(72) Inventors: Alexander KRUPYSHEV, Chelmsford, MA (US); Leigh F. SHARROCK, Londonderry, NH (US); Joseph HALLISEY, Pepperell, MA (US)

(21) Appl. No.: 15/889,811

(22) Filed: Feb. 6, 2018

Related U.S. Application Data
(60) Provisional application No. 62/455,874, filed on Feb. 7, 2017.

(51) Int. Cl. H01L 21/67; H01L 21/687; H01L 21/677; B25J 15/06

(52) U.S. Cl. CPC H01L 21/67196; H01L 21/67167; B25J 15/0616; H01L 21/67742; H01L 21/68707

(57) ABSTRACT

A substrate processing apparatus includes a linearly elongated substantially hexahedron shaped substrate transport chamber having linearly elongated sides of the hexahedron and at least one end wall of the hexahedron substantially orthogonal to the linearly elongated sides. A plurality of process modules are linearly arrayed along the at least one of the linearly elongated sides. A substrate transport arm is pivotally mounted within the substrate transport chamber so that a pivot axis of the substrate transport arm is mounted, fixed relative to the substrate transport chamber. The substrate transport arm has a three link—three joint SCARA configuration, of which one link is an end effector with at least one substrate holder, that is articulate to transport the substrate, and held by the at least one substrate holder, in and out of the substrate transport chamber through the end and side substrate transport openings.

### CROSS-REFERENCE TO RELATED APPLICATIONS

This Non-Provisional patent application claims priority to and the benefit of U.S. Provisional Patent Application No. 62/455,874, filed on Feb. 7, 2017, the disclosure of which is incorporated herein by reference in its entirety.

### BACKGROUND

### 1. Field

The exemplary embodiments generally relate to robotic systems and, more particularly, to robotic transport apparatus.

### 2. Brief Description of Related Developments

Through put is one measure by which semiconductor fabrication facility (referred to as a FAB) efficiency is determined. Increases in the through put of a FAB is always sought and welcomed. Another measure by which FAB efficiency is measured is flexibility of the FAB configuration (and the flexibility of the configuration of the processing tools and apparatus therein).

A prime factor on FAB throughput is through put of processing tools in which substrates are loaded, processed and unloaded after processing, and how efficiently the process modules fit into a given FAB space (i.e. how many processing tools fit into a given FAB space, and have a configuration that is optimized for through put). On the other hand, desire for even smaller transport chambers, has resulted in longer processing times for effecting process recipes in the processing tools and has resulted in a corresponding increase in substrate sizes, such as 400 mm and 450 mm and possibly even larger substrates attempting to mitigate effects of longer processing times on through put by application of scaling factors. The effects of processing substrates with ever increasing substrate sizes are, for example, larger processing tool components and longer processing times. For example, transport apparatus with longer reaches are required to process the larger substrates. Larger processing chambers, transport chambers and load locks with larger footprints are also required to process the larger substrates. One example, of a conventional processing tool 100 with larger processing tool components is illustrated in FIG. 1 and includes a transport chamber 114, a substrate transport arm 150 disposed within the transport chamber 114, load locks 110, 112 coupled to the transport chamber 114 and process modules 120, 122, 124, 126, 128, 130 coupled to the transport chamber 114. Here three process modules are coupled to each of the sides of the transport chamber where the substrate transport arm 150 includes an upper arm link 152, a forearm link 154 and end effectors 156, 158. FIG. 1 shows a conventional transport chamber 114 with a conventional transport arm 150 having a three link configuration (where one of the links is an end effector 156), plus another end effector 158 and is illustrative of the limits with this conventional approach. For example, the conventional configuration shown in FIG. 1 is substantially similar in length and width proportion (or aspect ratio) to that of a conventional hexagonal plan form processing tool 100′ as shown in FIG. 1A with a modest increase in process module capacity and in efficiency to compensate for process times.

The increase in the size of the process modules and load locks, for example, increase the processing time per substrate. This increase in processing time per substrate at one or more process modules/load locks may result in longer idle times of other process modules available in the processing tool for performing subsequent processes in the processing recipe of the substrate, with what may be readily realized deleterious effects on the processing tool through put. Such deleterious effects may naturally be ameliorated by increasing the number of process modules (not available with conventional transport chambers as noted above) and thus increasing the number of substrates within the processing tool at any given time for a given load/unload operation of the processing tool. Thus, a processing tool with a minimized footprint and large number of process modules (or a high density ratio of process modules to processing tool footprint) and corresponding component configuration effecting, yet with improved positioning characteristics of the substrate at a desired substrate location in the processing tool, is desired.

### BRIEF DESCRIPTION OF THE DRAWINGS

The foregoing aspects and other features of the disclosed embodiment are explained in the following description, taken in connection with the accompanying drawings, wherein:

FIGS. 1 and 1A are schematic illustrations of prior art substrate processing tools with different configurations;

FIG. 2A is a schematic illustration of a substrate processing tool in accordance with aspects of the disclosed embodiment;

FIGS. 2B, 2C, 2D, 2E, 2F, 2G, 2H and 21 are schematic illustrations of portions of the substrate processing tool of FIG. 2A in accordance with aspects of the disclosed embodiment;

FIGS. 3A-3D are schematic illustrations of drive sections of a transport apparatus of the substrate processing tool in FIGS. 2A-2E.

FIG. 4 is a schematic illustration of a portion of a substrate transport apparatus of the substrate processing tool in FIGS. 2A-2E in accordance with aspects of the disclosed embodiment;

FIG. 5 is a schematic illustration of the substrate processing tool in FIGS. 2A-2E in accordance with aspects of the disclosed embodiment;

FIG. 6 is a schematic illustration of the substrate processing tool in FIGS. 2A-2E in accordance with aspects of the disclosed embodiment;

FIGS. 7, 8, 9A, 9B, 10, 11, 12 and 12A are schematic illustrations of the substrate processing tool of FIGS. 2A-2E arranged in different substrate processing tool configurations in accordance with aspects of the disclosed embodiment;

FIGS. 13A, 13B, 13C and 13D are schematic illustrations of an operation of the substrate processing tool in accordance with aspects of the disclosed embodiment;

FIGS. 14A, 14B and 14C are schematic illustrations of an operation of the substrate processing tool in accordance with aspects of the disclosed embodiment;

FIGS. 15A, 15B and 15C are schematic illustrations of an operation of the substrate processing tool in accordance with aspects of the disclosed embodiment;

FIGS. 16A, 16B and 16C are schematic illustrations of an operation of the substrate processing tool in accordance with aspects of the disclosed embodiment; and

FIG. 17 is an exemplary flow diagram in accordance with aspects of the disclosed embodiment.

### DETAILED DESCRIPTION

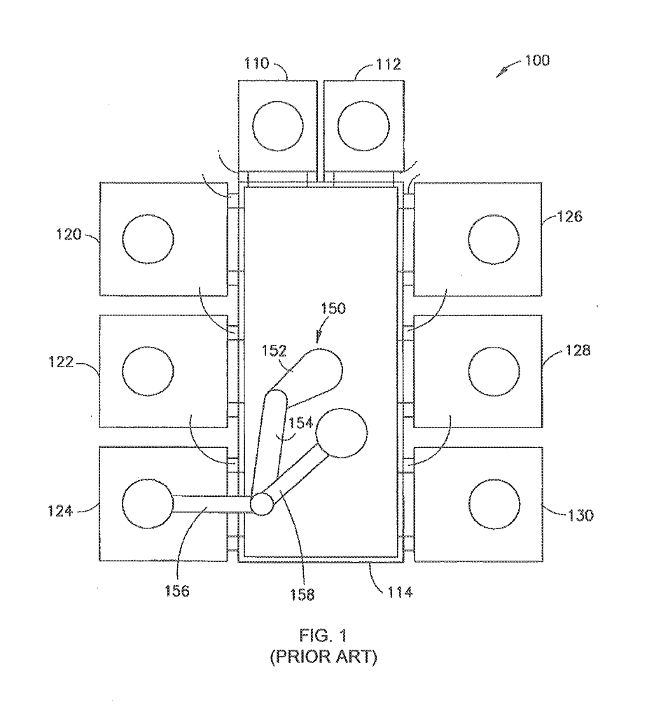

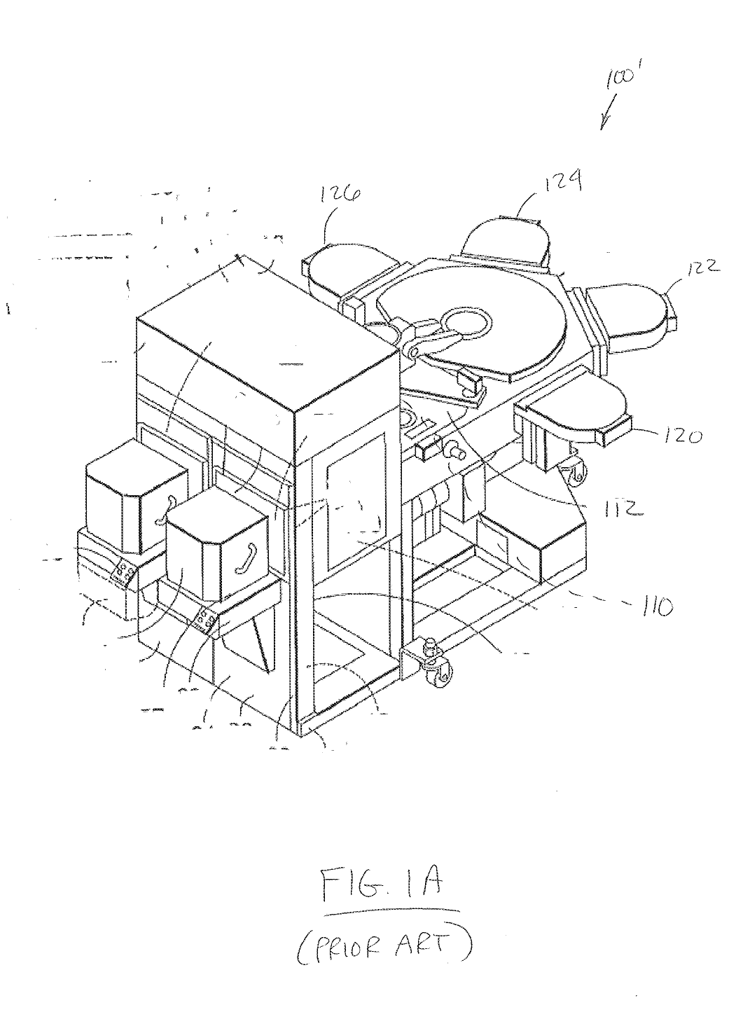

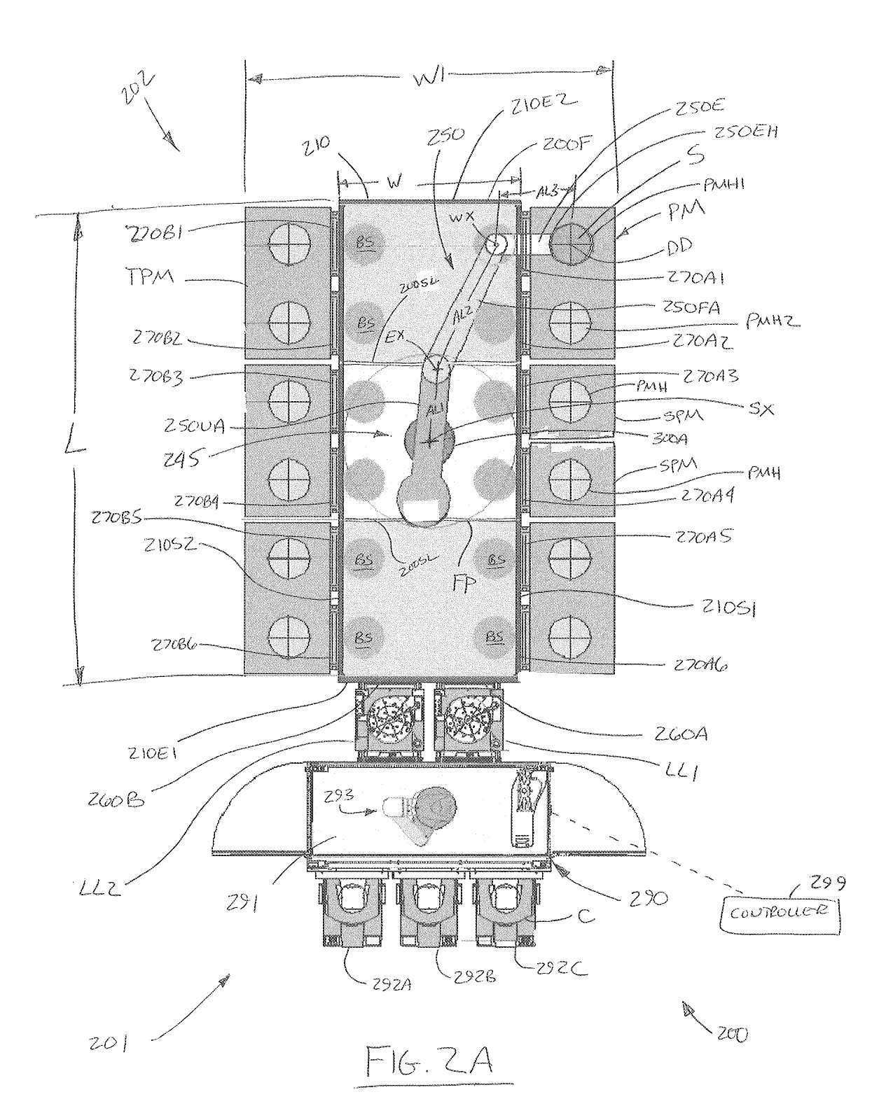

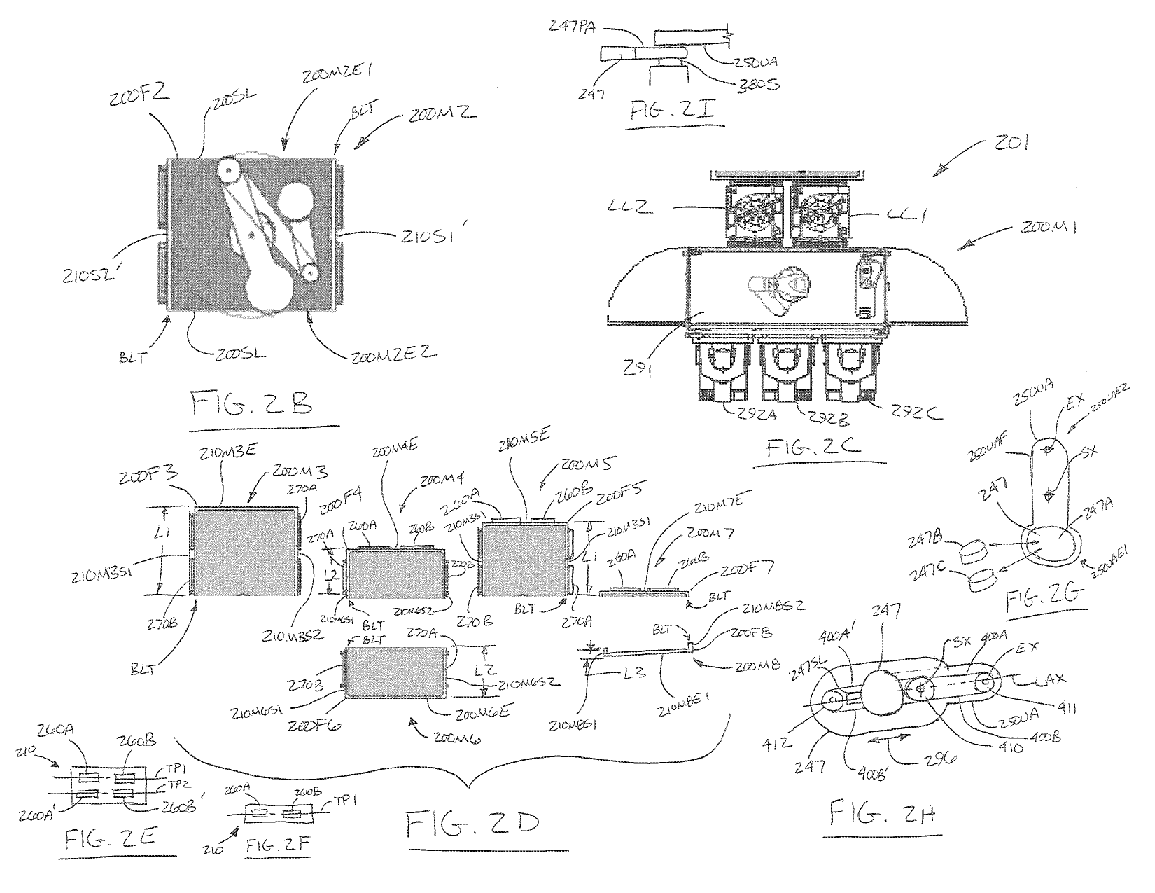

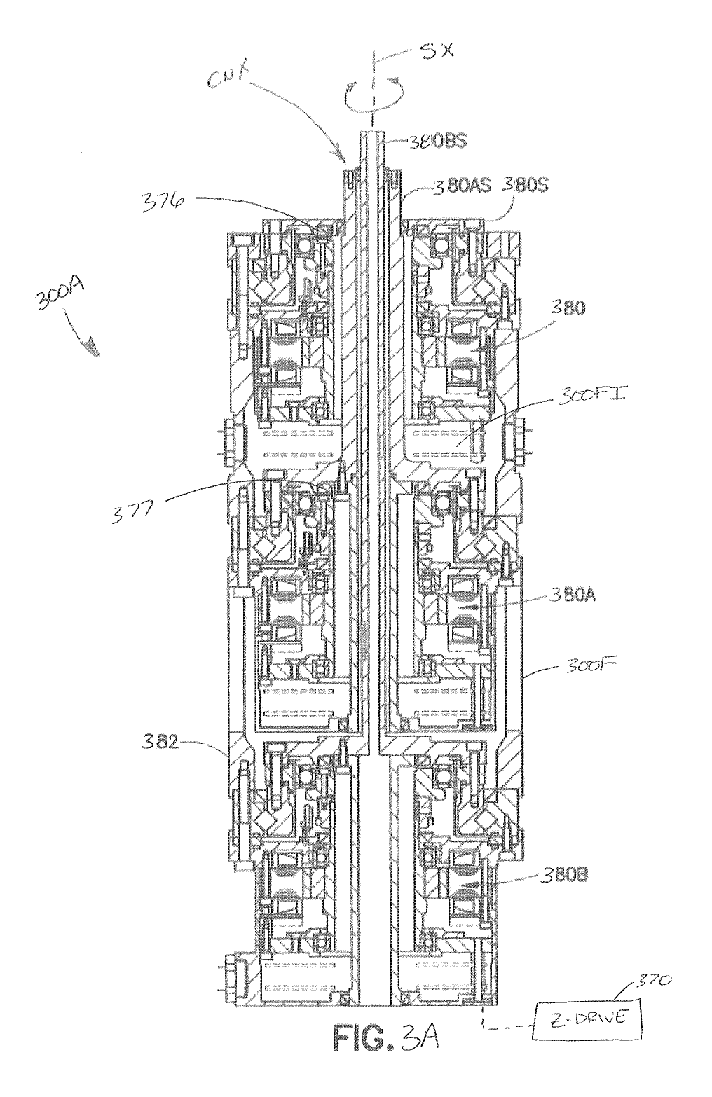

Referring to FIGS. 2A-2E, the aspects of the disclosed embodiment provide a substrate processing tool 200 that has a linear processing tool configuration and that is adjustable for increased substrate processing tool through put as well as increased efficiency, where the substrate processing tool 200 has a higher process module density for a given space (such as a width W1 of the substrate processing tool 200) compared to conventional substrate processing tools, such as those described above. The aspects of the disclosed embodiment described herein provide for the substrate processing tool 200 being modular such that the number of process modules PM coupled to the transport chamber 210 can be effected through modularity of the transport chamber 210, without increasing a width W of the transport chamber 210, by simply increasing the transport chamber length L. Moreover, the modular transport chamber 210 described herein may be accommodated within existing space (such as a width) of conventional substrate processing tools, such as the conventional substrate processing tool 100 illustrated in FIG. 1 having a twin load lock configuration at one end of the processing tool that is substantially akin to a conventional processing tool having a hexagonal plan/octahedron transport chamber with a length to width aspect ratio of about 1:1 or less than 2:1.

In one aspect, the substrate processing tool 200 includes a front end 201, a back end 202 and any suitable controller 299 for controlling operation of the substrate processing tool 200 in the manner described herein. In one aspect, the controller 299 may be part of any suitable control architecture such as, for example, a clustered architecture control. The control system may be a closed loop controller having a master controller (which in one aspect may be controller 110), cluster controllers and autonomous remote controllers such as those disclosed in U.S. Pat. No. 7,904,182 entitled “Scalable Motion Control System” issued on Mar. 8, 2011 the disclosure of which is incorporated herein by reference in its entirety. In other aspects, any suitable controller and/or control system may be utilized.

In one aspect, the front end 201 may be an atmospheric front end that includes an equipment front end module (EFEM) 290, load ports 292A-292C and one or more load locks LL1, LL2. In one aspect, the equipment front end module 290 includes a transport chamber 291 to which the one or more load ports 292A-292C are coupled. The load ports 292A-292B are configured to hold substrate cassettes/carriers C in which substrates S are held for loading and unloading from the substrate processing tool 200 through the load ports 292A-292B. The one or more load locks LL1, LL2 are coupled to the transport chamber 291 for transferring substrates S between the transport chamber 291 and the back end 202.

The back end 202 may be a vacuum back end. It is noted that the term vacuum as used herein may denote a high vacuum such as 10⁻⁵ Torr or below in which the substrates are processed. In one aspect, the back end 202 includes a linearly elongated substantially hexahedron shaped transport chamber 210 having linearly elongated sides 210S1, 210S2 and end walls 210E1, 210E2 extending between the sides 210S1, 210D2. In one aspect, the sides 210S1, 210S2 have a length L and the end walls 210E1, 210E2 have a width W so that the hexahedron shaped transport chamber 210 has a side length L to width W aspect ratio that is a high aspect ratio, and the width W is compact with respect to a footprint FP (e.g. a minimum swing diameter of the substrate transport arm with the substrate transport arm in a fully retracted configuration) of a substrate transport arm 250 disposed within the transport chamber 210. The width W is compact with respect to the footprint FP of the transport arm 250 in that only sufficient minimum clearance is provided between the side walls 210S1, 210S2 and the footprint FP to allow operation of the substrate transport arm 250 as described herein. In one aspect, the aspect ratio of the transport chamber 210 is greater than 2:1, and the substrate transport arm footprint is compact for a predetermined maximum reach of the substrate transport arm; while in other aspects, the aspect ratio is about 3:1, and the substrate transport arm footprint is compact for a predetermined maximum reach of the substrate transport arm.

In one aspect, a side substrate transport opening 270A1-270A6, 270B1-270B6, from the linear array of side substrate transport openings 270A1-270A6, 270B1-270B6, disposed proximate another end wall 210E1, 210E2 of the hexahedron shaped substrate transport chamber 210 opposite the at least one end wall 210E1, 210E2, is oriented so that a corresponding axis of substrate holder motion 270A1X-270A6X, 270B1X-270B6X (see FIG. 6) through the side substrate transport opening 270A1-270A6, 270B1-270B6 proximate the opposite end wall 210E1, 210E2 is substantially orthogonal to another axis of substrate holder motion 260AX, 260BX through the end substrate transport opening 260A, 260B of the at least one end wall 250E1, 250E2. For example, at least one end wall 210E1, 210E2 of the hexahedron shaped transport chamber 210 is substantially orthogonal to the linearly elongated sides 210S1, 210S2. The at least one end wall 210E1, 210E2 has at least one end substrate transport opening 260A, 260B. At least one of the linearly elongated sides 210S1, 210S2 has a linear array of side substrate transport openings 270A1-270A6, 270B1-270B6. In one aspect, another of linearly elongated sides 210S1, 210S2 opposite the at least one linearly elongated side 210S1, 210S2 of the substrate transport chamber 210 has at least one other side substrate transport opening 270A1-270A6, 270B1-270B6, and the substrate transport arm 250 is configured to transport the substrate S, held by at least one substrate holder 250EH of an end effector 250E, 250E1, 250E2 of a substrate transport arm 250, 250A1, 250A2, in and out of the substrate transport chamber through the end, side, and other side substrate transport openings 260A, 260B, 270A1-270A6, 270B1-270B6 so that the end effector 250E, 250E1, 250E2 is common to each of the end, side and other substrate transport openings 260A, 260B, 270A1-270A6, 270B1-270B6 respectively disposed in the end wall 210E1, 210E2 and the linearly elongated side 210S1, 210S2 and the linearly elongated opposite side 210S1, 210S2 of the substrate transport chamber 210. In one aspect, each opening of the end substrate transport openings 260A, 260B and side substrate transport openings 270A1-270A6, 270B1-270B6 is arranged for transferring a substrate S there through in and out of the transport chamber 210. In one aspect, a corresponding axis of substrate holder motion 270A1X-270A6X, 270B1X-270B6X through each side substrate transport opening 270A1-270A6, 270B1-270B6 extends substantially parallel with each other respectively through each substrate transport opening 270A1-270A6, 270B1-270B6. In one aspect, the substrate transport chamber 210 includes a buffer station BS adjacent at least one of the openings 260A, 260B, 270A1-270A6, 270B1-270B6 on which substrates are buffered during transport within the substrate transport chamber 210.

In one aspect, at least one end wall 210E1, 210E2 is dimensioned to accept alongside, two side by side load locks LL1, LL2 or other process modules PM (see e.g. FIGS. 7, 9A, 9B and 11) placed proximately adjacent each other on a common level or plane (e.g. substrate transport plane TP1 as shown in FIG. 2F which illustrates only end openings for exemplary purposes only) and commonly facing the respective end wall 210E1, 210E2. It should be understood that while the substrate transport chamber 210 is illustrated in the figures as having two end openings 260A, 260B on one or more end walls 210E1, 210E2, that in other aspects only one end opening may be provided on one or more of the end walls 210E1, 210E2 such that only one load lock or process module is coupled to the respective end wall 210E, 210E2. Similarly, the sides 210S1, 210S2 are configured to accept alongside, side by side process modules PM or load locks LL1, LL2 placed proximately adjacent each other on a common level or plane (e.g. substrate transport plane TP1) and commonly facing the respective side 210S1, 210S2. In other aspects, load locks LL1, LL2 and/or the process modules PM may be stacked on different levels or planes (e.g. substrate transport planes TP1, TP2), one above the other, on the respective end wall 210E1, 210E2 or sides 210S1, 210S2 so as to form any suitable grid (having any suitable size) of openings 260A, 260B, 260A′, 260B′, 270A, 270B (see FIG. 2E illustrating only the end openings for exemplary purposes) for connecting process modules PM or load locks LL1, LL2 to the transport chamber 210. In one aspect, the process modules PM are tandem processing modules TPM (e.g. two substrate holding stations PMH1, PMH2 within a common housing and coupled to two side by side openings of the substrate transport chamber); while in other aspects the process modules may be single process modules SPM (e.g. one substrate holding station PMH within a housing and coupled to a single opening of the substrate transport chamber—see FIG. 2A) or a combination of single and tandem process modules coupled to respective openings of a common substrate transport chamber 210 (see FIG. 2A).

In one aspect, the substrate processing tool 200 includes a plurality of process modules PM linearly arrayed along at least one of the linearly elongated sides 210S1, 210S2 and respectively communicating with the transport chamber 210 via corresponding side substrate transport openings 270A1-270A6, 270B1-270B6. In one aspect, the process module PM linear array provides at least six process module substrate holding stations PMH, PMH1, PMH2 distributed along at least one linearly elongated side 210S1, 210S2 at a substantially common level, and each of the substrate holding stations is accessed with a common end effector 250E, 250E1, 250E2 of the substrate transport arm 250, 250A, 250B through the corresponding side transport openings 270A1-270A6, 270B1-270B6. While three process modules PM are generally illustrated on each side 210S1, 210S1 of the substrate transport chamber 210 (with the exception of the single process modules SPM in FIG. 2A), there may be more than three process modules PM or less than three process modules PM on each side 210S1, 210S2 providing any suitable number of substrate holding stations on each side 210S1, 210S2. In one aspect, the side openings 270A1-270A6, 270B1-270B6 and the process modules PM may be arranged on different levels to form a grid of openings and process modules in a manner substantially similar to that described herein with respect to FIG. 2E and the end wall 210E1, 210E2 openings 260A, 260B, 206A′, 260B′ (where the transport apparatus 245 includes a Z-axis drive to raise and lower the end effector 250E, 250E1, 250E2 to the different levels TP1, TP2). In one aspect, the process modules PM may operate on the substrates through various deposition, etching, or other types of processes to form electrical circuitry or other desired structure on the substrates. Typical processes include but are not limited to thin film processes that use a vacuum such as plasma etch or other etching processes, chemical vapor deposition (CVD), plasma vapor deposition (PVD), implantation such as ion implantation, metrology, rapid thermal processing (RTP), dry strip atomic layer deposition (ALD), oxidation/diffusion, forming of nitrides, vacuum lithography, epitaxy (EPI), wire bonder and evaporation or other thin film processes that use vacuum pressures.

Referring to FIGS. 2A, 2B and 2C, as described above the substrate processing tool 200 has a modular configuration. In one aspect, the front end 201 may be one module (e.g. the front end module 200M1) of the substrate processing tool 200 such that any suitable front end having a transport chamber 291, load ports 292A-292C and load locks LL1, 1L2 may be coupled to the substrate transport chamber 210 through end openings 260A, 260B on one or more end walls 210E1, 210E2 of the substrate transport chamber 210. In one aspect, the transport chamber 210 forms another module of the substrate processing tool where the transport chamber 210 includes a common or core module 200M2 and one or more chamber end or insert modules 200M3, 200M4, 200M5, 200M6, 200M7, 200M8. In one aspect, the core module 200M2 includes a frame 200F2 and the at least one substrate transport apparatus 245 is mounted to the frame 200F1 in any suitable manner. Each of the insert modules 200M3, 200M4, 200M5, 200M6, 200M7, 200M8 also include a respective frame 200F3, 200F4, 200F5, 200F6, 200F7, 200F8 which when joined to the frame 200F2 of the core modules 200M2 forms the frame 200F of the substrate transport chamber 210.

In one aspect, each of the insert modules 200M3, 200M4, 200M5, 200M6, 200M7, 200M8 has a different configuration such that they are selectable for connection to the core module 200M2 for providing the substrate transport chamber 210 with linearly elongated sides 210S1, 210S2 that have a selectably variable length L wherein the sides 210S1, 210S2 of the substrate transport chamber are selectable between different lengths and define a selectably variable configuration of the substrate transport chamber. For example, insert module 200M3 includes sides 210M3S1, 210M3S2 where each side 210M3S1, 210M3S2 has a length L1 and includes, for example, two of the side openings 270A1-270A6, 270B1-270B6 (referred to generally in FIG. 2D as openings 270A and 270B), while the end wall 210M3E1 of the insert module 200M3 does not have any openings through which the end effector 250E, 250E1, 250E2 passes. The insert module 200M5 is substantially similar to insert module 200M3 however, the end wall 210M5E of insert module 200M5 includes openings 260A, 260B. Similarly, insert module 200M6 includes sides 210M6S1, 210M6S2 where each side 210M6S1, 210M6S2 has a length L2 and includes, for example, one of the side openings 270A, 270B, while the end wall 210M6E1 of the insert module 200M6 does not have any openings through which the end effector 250E, 250E1, 250E2 pass. The insert module 200M4 is substantially similar to insert module 200M6 however, the end wall 210M4E of insert module 200M4 includes openings 260A, 260B. Insert module 200M8 includes sides 210M8S1, 210M8S2 where each side 210M8S1, 210M8S2 has a length L3 and does not include any side openings, while the end wall 210M8E1 of the insert module 200M8 does not have any openings through which the end effector 250E, 250E1, 250E2 pass. The insert module 200M7 is substantially similar to insert module 200M8 however, the end wall 210M7E of insert module 200M7 includes openings 260A, 260B. The insert modules 200M3, 200M4, 200M5, 200M6, 200M7, 200M8 are coupled to the core module 200M2 in any suitable manner such as a bolt on interface BLT where any suitable seal 200SL is provided between each of the insert modules 200M3, 200M4, 200M5, 200M6, 200M7, 200M8 and the respective end 200M2E1, 200M2E2 of the core module 200M2.

In this aspect, the length L1 of insert modules 200M3, 200M5 is larger than length L2 of the insert modules 200M4, 200M6; and the length L2 of the insert modules 200M4, 200M6 is larger than the length L3 of the insert modules 200M7, 200M8. Further, while the insert modules are illustrated as having no side openings, one side opening 270A, 270B on each side, and two side openings 270A, 270B on each side, with or without the end openings 260A, 260B, in other aspects the insert modules may have any suitable number of side openings 270A, 270B and any suitable lengths for providing the substrate transport chamber 210 with the variable length and any suitable number of side openings 270A, 270B and end openings 260A, 260B disposed on one or more ends 210E1, 210E2 of the substrate transport chamber 210. For example, referring to FIGS. 7, 8, 9A, 9B, 10, 11 and 12 the substrate transport chamber 210 is illustrated having selectably variable configurations where the configuration is selectable between a configuration where the side length L to width W (see FIG. 2A) aspect ratio varies from high aspect ratio (such as 3:1 or greater) to unity (e.g. 1:1) aspect ratio, and wherein the substrate transport arm 250 is common to each selectable configuration of the substrate transport chamber 210.

As can be seen in FIG. 7, the substrate transport chamber 210 includes the core module 200M2 and two of the insert modules 200M5 coupled to each end 200M2E1, 200M2E2 of the core module 200M2. In this aspect, the insert modules 200M5 are selected to provide the substrate transport chamber 210 with a length L to width W aspect ratio of 3:1 while providing end openings 260A, 260B on each end wall 210E1, 210E2 of the substrate transport chamber 210. The configuration of the substrate transport chamber 210 illustrated in FIG. 8 also includes insert modules 200M5, 200M6 that are selected such that the substrate transport chamber 210 has a length L to width W aspect ratio of 3:1; however in this aspect, only one end wall 210E1 of the transport chamber includes end openings 260A, 260B while end wall 210E2 does not include any openings. In this aspect, insert module 200M5 is coupled to the first end 200M2E1 of the core module 200M2 and insert module 200M6 is coupled to the second end 200M2E2 of the core module 200M2.

As can be seen in FIGS. 9A and 9B, the substrate transport chamber 210 includes the core module 200M2 and two insert modules 200M4 that are selected to provide the substrate transport chamber 210 with a length L to width W aspect ratio of 2:1. Here one of the insert modules 200M4 is coupled to the first end 200M2E1 of the core module while the other insert module 200M4 is coupled to the second end 200M2E2 of the core module 200M2 to provide the 2:1 aspect ratio while also providing the substrate transport chamber 210 with end openings 260A, 260B at each end wall 210E1, 210E2 of the substrate transport chamber 210. Although not shown in the figures, the insert module 200M4 coupled to the second end 200M2E2 of the core module 200M2 may be replaced with insert module 200M6 so that end openings 260A, 260B are only provided at end wall 210E1 of the substrate transport chamber 210 in a manner substantially similar to that illustrated in FIG. 8.

The configuration of the substrate transport chamber 210 illustrated in FIG. 10 also includes insert modules 200M3, 200M7 that are selected such that the substrate transport chamber 210 has a length L to width W aspect ratio of 2:1; however in this aspect, only one end wall 210E2 of the transport chamber includes end openings 260A, 260B while end wall 210E2 does not include any openings. In this aspect, insert module 200M3 is coupled to the second end 200M2E2 of the core module 200M2 so that the core module 200M2 and the insert module 200M3 provide each side wall 210S1, 210S2 of the substrate transport chamber 210 with four side openings 270A, 270B. The insert module 200M7 is coupled to the first end 200M2E1 of the core module 200M2 such that the load locks LL1, LL2 of the front end module 200M1 can be coupled to the substrate transport chamber 210, where the insert module 200M7 only includes end openings 260A, 260B. Although not shown in the figures, the insert module 200M6 coupled to the second end 200M2E2 of the core module 200M2 may be replaced with insert module 200M5 so that end openings 260A, 260B are provided at both end walls 210E1, 210E2 of the substrate transport chamber 210 in a manner substantially similar to that illustrated in FIGS. 7, 9A and 9B.

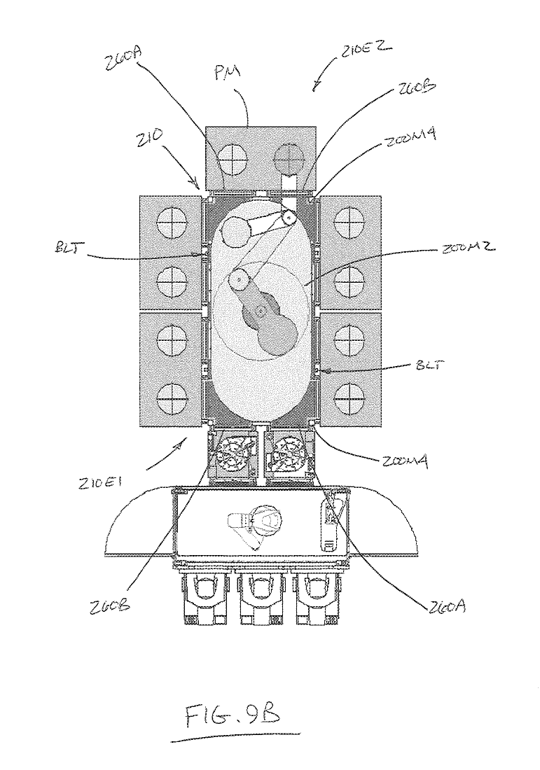

The configuration of the substrate transport chamber 210 illustrated in FIG. 11 includes two of insert modules 200M7 that are selected such that the substrate transport chamber 210 has a length L to width W aspect ratio of 1:1 (e.g. a unity aspect ratio). In this aspect, both end walls 210E1, 210E2 of the transport chamber include end openings 260A, 260B. In this aspect, one of the insert modules 200M7 is coupled to the second end 200M2E2 of the core module 200M2 while the other one of the insert modules 200M7 is coupled to the first end 200M2E1 of the core module 200M2 such that only the core module 200M2 provides each side wall 210S1, 210S2 of the substrate transport chamber 210 with two side openings 270A, 270B. The insert modules 200M7 in this aspect are coupled to the core module 200M2 such that the load locks LL1, LL2 of the front end module 200M1 can be coupled to the substrate transport chamber 210 and so that process modules PM can be coupled to the second end 210E2 of the substrate transport chamber 210, where the insert modules 200M7 only includes end openings 260A, 260B. In one aspect, as illustrated in FIG. 12, the insert module 200M7 coupled to the second end 200M2E2 of the core module 200M2 may be replaced with insert module 200M8, which serves to cap the second end 200M2E2 of the core module 200M2 without providing any side openings or end openings, such that the substrate transport chamber maintains the 1:1 length L to width W aspect ratio while proving end openings 260A, 260B only on the end wall 210E1 of the substrate transport chamber 210. In one aspect, as illustrated in FIG. 12A, insert module 200M7 may be coupled to the ends 200M2E1, 200M2E2 of the core module 200M2 where a process module PM may be located on one or more of the sides 210S1, 210S2 and/or the second end 210E2 of the substrate transport chamber 210 (where one or more load locks are coupled to the first end 210E1 of the substrate transport chamber 210). While exemplary configurations of the substrate transport chamber 210 have been illustrated in FIGS. 7, 8, 9A, 9B, 10, 11 and 12, it should be understood that any number of core modules 200M2 and any number of insert modules 200M may be combined in any suitable manner to provide the substrate transport chamber 210 with any suitable length L to width W aspect ratio having any suitable number of side openings 270A, 270B and end openings 260A, 260B.

Referring again to FIGS. 2A and 2E, in one aspect, at least one substrate transport apparatus 245 is disposed at least partially within the transport chamber 210. In one aspect, each of the substrate transport apparatus 245 includes a substrate transport arm 250 that is pivotally mounted within the transport chamber 210 so that a pivot axis (e.g. shoulder axis) SX of the substrate transport arm 250 is mounted fixed relative to the transport chamber 210 so that the pivot axis SX does not traverse the length L or width W of the substrate transport chamber 210. In one aspect, the fixed mounting of the pivot axis SX is advantageous, compared to mounting the transport arm 250 to a linear translator, in that the fixed mounting of the pivot axis SX minimizes particle generation within the transport chamber 210 and limits or eliminates any sealing interface isolating sliding features to effect location of the pivot joint SX. Further, in contrast to conventional articulated arms configured with a pivot link (on which the transport arm is mounted) the articulated transport arm 250 described herein provides long reach, for a compact footprint, to allow transfer between one end wall 210E1 (e.g. the load locks LL1, LL2 connected thereto), the other end wall 210E1 (e.g. load locks or process modules connected thereto) and the process modules PM disposed there between along the sides 210S1, 210S2 of the high aspect ratio transport chamber 210 resolving droop effects (as exhibited by conventional arms); provides the substrate transport arm 250 with substantially unrestricted arm mobility for the corresponding long reach, as described below; and provides pivot stiffness for high accuracy substrate positioning at the long reach (such as at side openings 270A1, 270A6, 270B1, 270B6 and end openings 260A, 260B.

In one aspect, the substrate transport arm 250 has a three link—three joint SCARA (Selective Compliant Articulated Robot Arm) configuration. For example, the substrate transport arm 250 includes a first arm link or upper arm 250UA, a second arm link or forearm 250FA and at least a third arm link or at least one end effector 250E, 250E1, 250E2 where each end effector 250E, 250E1, 250E2 includes at least one substrate holder 250EH (the kinematic control of which effect complete transport motion and positioning of the substrate holder 250EH throughout the range of motion of the substrate transport arm 250). In one aspect, referring to FIG. 2A, the substrate transport arm 250 includes a single end effector 250E having a single substrate holder 250EH. In one aspect, referring to FIG. 5, the substrate transport arm 250A includes a single end effector 250E1 having more than one substrate holder 250EH. In the aspect, illustrated in FIG. 5, the end effector 250E1 is provided with two substrate holders 250EH but in other aspects any suitable number of substrate holders may be provided so that substrates S disposed in a side by side arrangement are substantially simultaneously picked and placed from side by side substrate holding stations PMH1, PMH2. For example, the substrate holders 250EH of the end effector 250E1 are arranged so that the end effector 250E1 extends or retracts the more than one substrate holder 250EH substantially simultaneously through more than one of the linearly arrayed side substrate transport openings 270A1-270A6, 270B1-270B6 (or linearly arrayed openings 260A, 260B on one or more of the end walls 210E1, 210E2) with a common end effector motion. In one aspect, the substrate transport arm 250B includes more than one end effector, such as end effectors 250E, 250E2 where the end effectors 250E, 250E2 are dependent from a common forearm link 250FA of the substrate transport arm 250B so that the end effectors 250E, 250E2 pivot relative to the forearm 250FA about a common rotation axis (e.g. the wrist axis WX), and where both end effectors 250E, 250E2 are common to each of the end and side substrate transport openings 260A, 260B, 270A1-270A2, 270B1-270B2. Where the substrate transport arm 250B includes more than one end effector 250E, 250E2, the end effectors 250E, 250E2 provide the substrate transport arm 250B with a fast swap end effector that is common to each of the end and side substrate transport openings 260A, 260B, 270A1-270A2, 270B1-270B2. In one aspect, each end effector 250E, 250E2 is independently rotationally driven by a respective degree of freedom of the drive section 300A, 300B, 300C, 300D while in other aspects the end effectors 250E, 250E2 may be differentially driven by a common degree of freedom of the drive section 300A, 300B, 300C, 300D in a manner substantially similar to that described in U.S. Pat. No. 9,401,294 issued on Jul. 26, 2016 (the disclosure of which is incorporated herein by reference in its entirety), such as where one of the end effectors 250E, 250E2 is driven by any suitable reverse transmission drive.

Referring to FIG. 4, in one aspect, the end effectors 250E, 250E1, 250E2 and each of the upper arm 250UA and forearm 250FA may be driven by any suitable drive section 300A, 300B, 300C, 300D (described below—drive section 300A is illustrated in FIG. 4 as an example) using any suitable transmissions. For example, in one aspect, the substrate transport arm 250, 250A, 250B includes a split band transmission substantially similar to those described in United States patent publication number 2015/0128749 published on May 14, 2015 and in U.S. Pat. No. 5,682,795 issued on Nov. 4, 1997; U.S. Pat. No. 5,778,730 issued on Jul. 14, 1998; U.S. Pat. No. 5,794,487 issued on Aug. 18, 1998; U.S. Pat. No. 5,908,281 issued on Jun. 1, 1999; and U.S. Pat. No. 6,428,266 issued on Aug. 6, 2002, the disclosures of which are incorporated herein by reference in their entireties. For example, referring to the drive transmission 400 for the forearm 250FA (it should be understood that the drive transmission for the end effector(s) is substantially similar), a shoulder pulley 410 may be mounted to the drive section 300A about the shoulder axis SX so that one of the drive shafts of the drive section 300A drives rotation of the shoulder pulley 410. An elbow pulley 411 is rotatably mounted at the elbow axis EX so that the elbow pulley 411 rotates with the forearm 250FA about the elbow axis EX as a unit. Drive bands 400A, 400B having any suitable height are partially wrapped around pulleys 410, 411 in opposite directions so that the bands 400A, 400B are both in tension during operation of the substrate transport arm 250 to provide stiffness to at least the joints EX, WX of the substrate transport arm 250.

Referring again to FIGS. 2A and 2E, in one aspect, the upper arm 250UA has a first length AL1 from joint SX center to joint EX center; the forearm 250FA has a second length AL2 from joint EX center to joint WX center; and the end effector 250E has a third length AL3 from joint center WX to a substrate holding reference datum DD of the substrate holder 250EH. In one aspect, one or more of the first length AL1, the second length AL2 and the third length AL3 is different than one or more other ones of the first length AL1, the second length AL2 and the third length AL3 (i.e. the transport arm 250 has unequal length arm links). In one aspect, the length AL2 may be longer than the lengths AL1 and AL3.

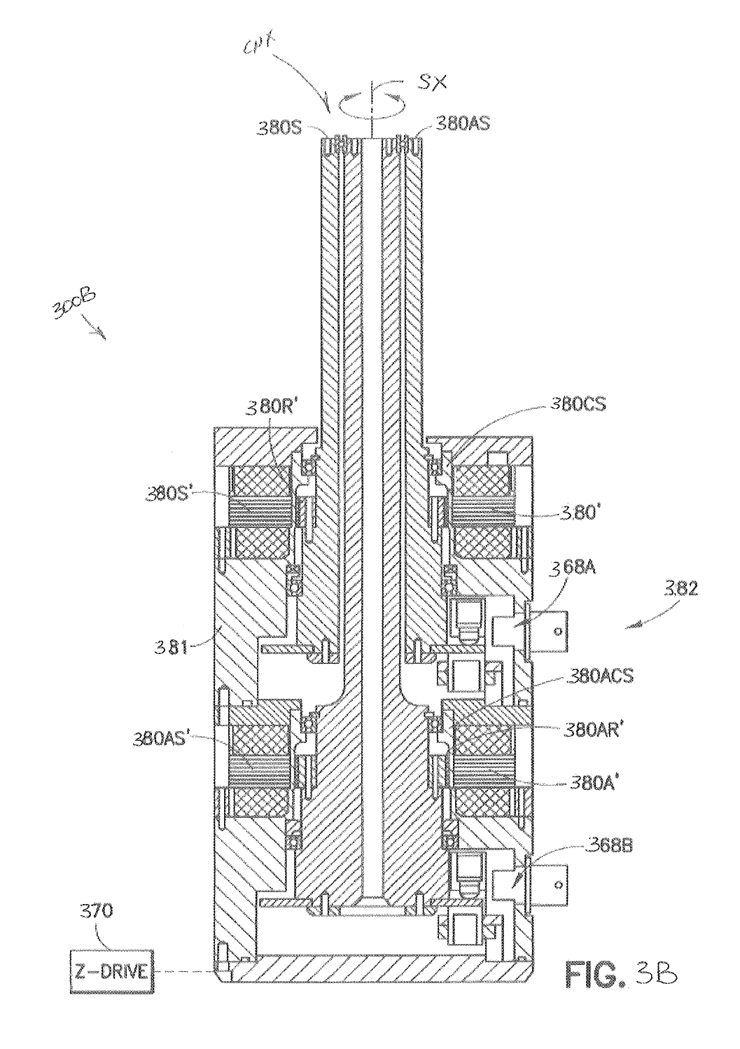

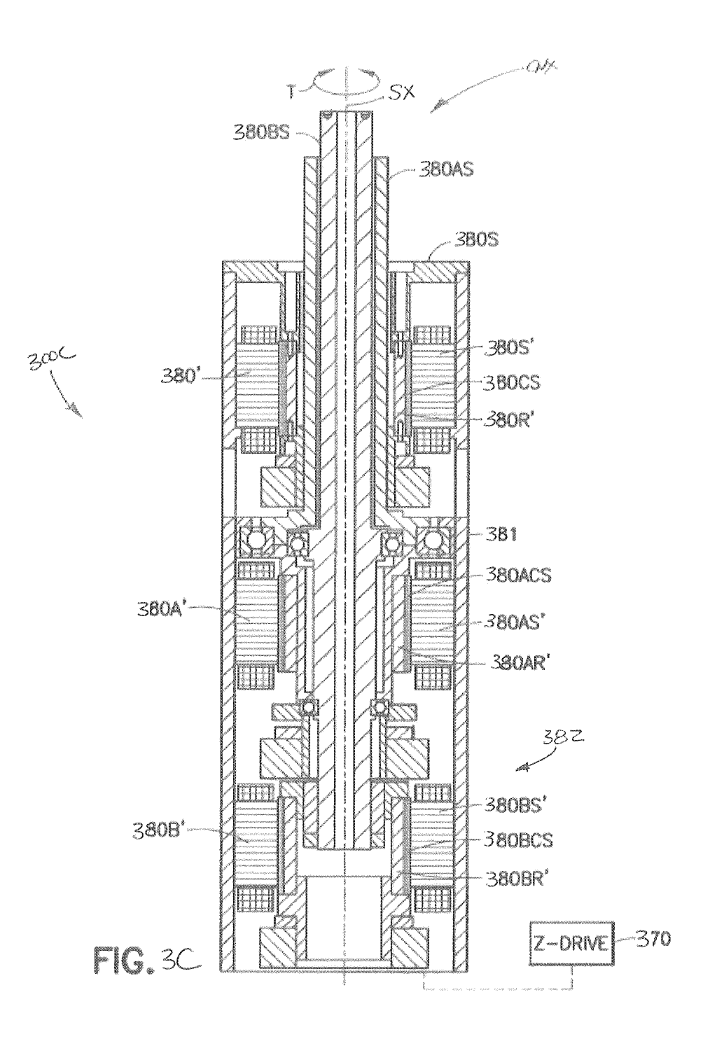

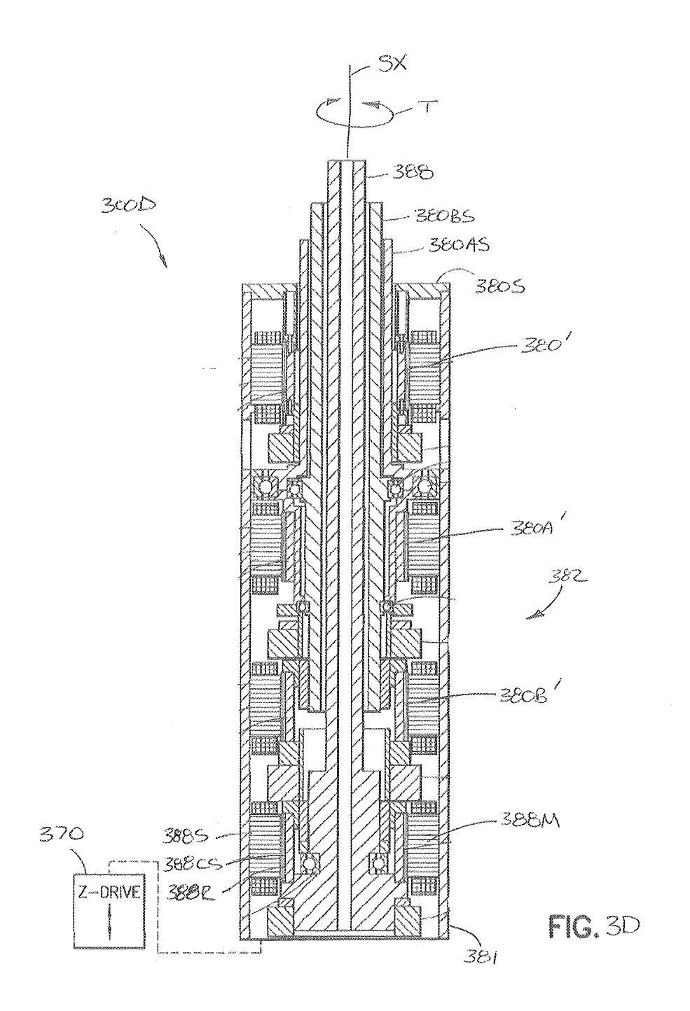

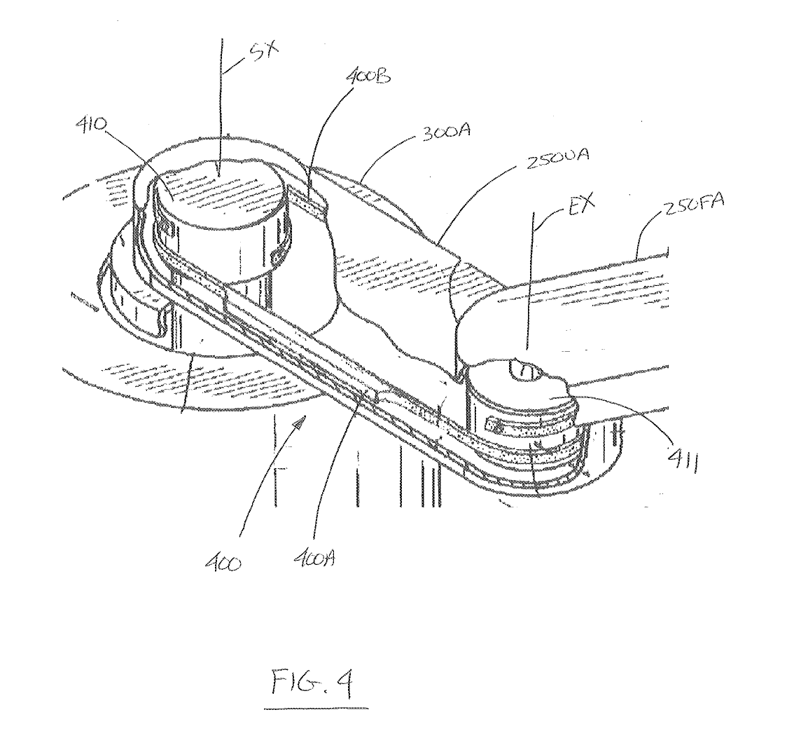

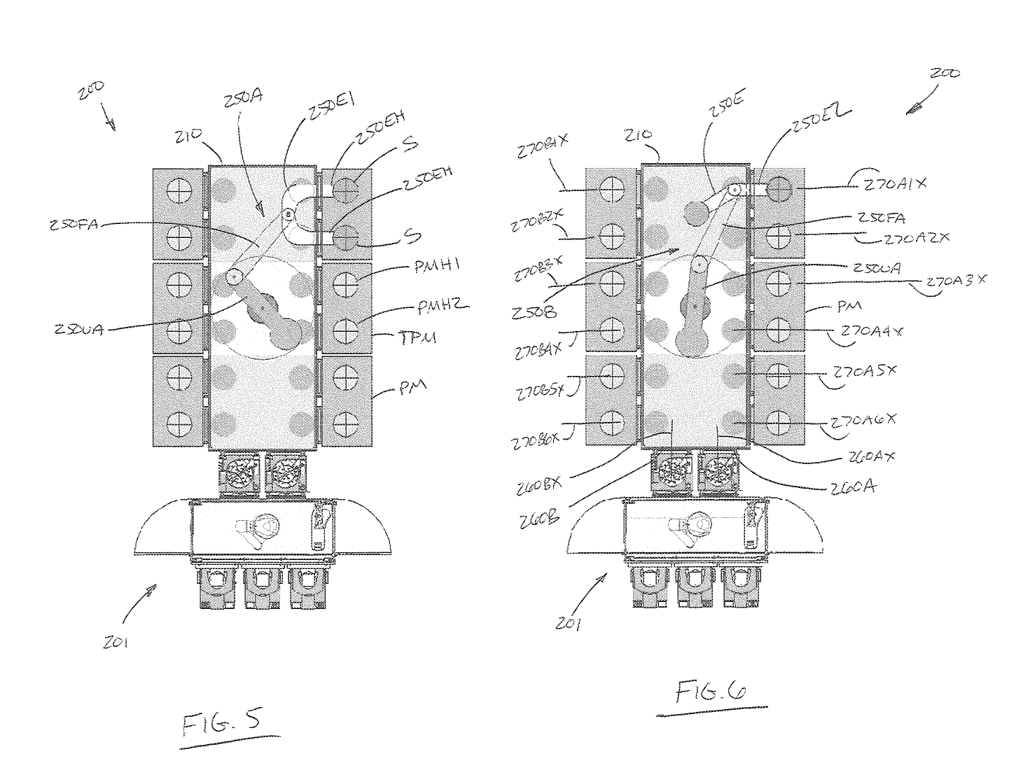

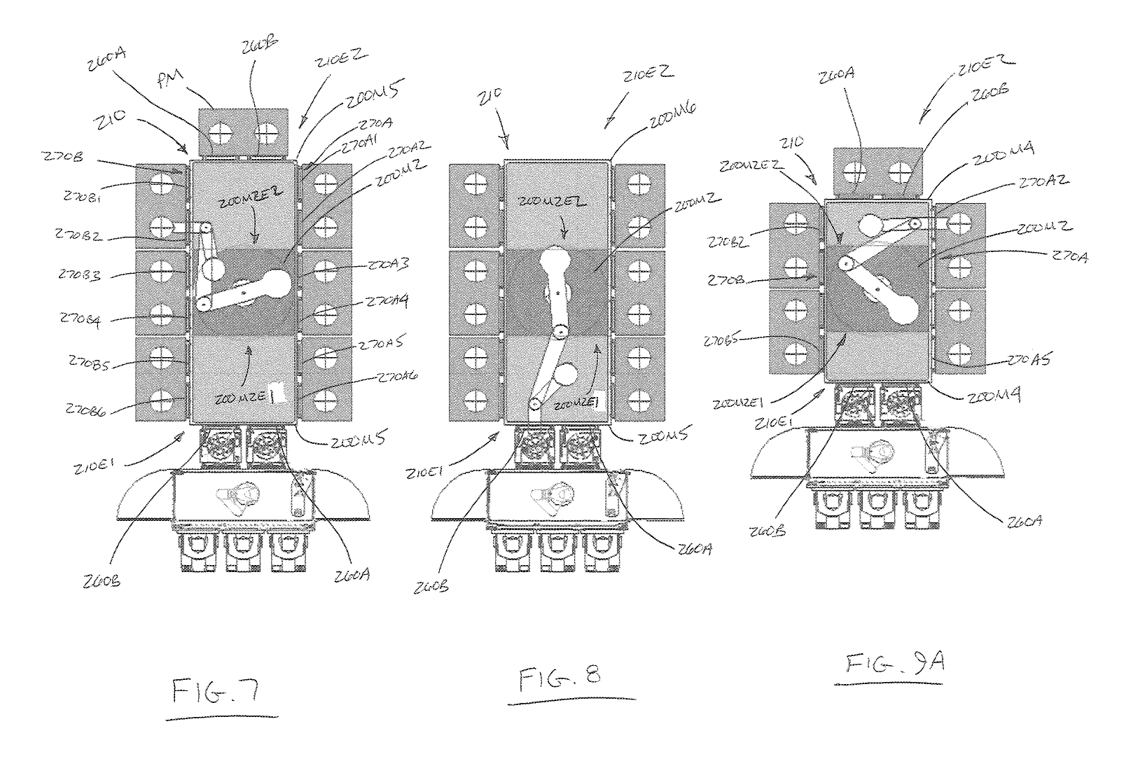

A first end 250UAE1 of the upper arm 250UA is rotatably coupled to, for example, any suitable drive section, such as drive sections 300A, 300B, 300C, 300D (see FIGS. 3A-3D) described herein, at the pivot joint SX for providing the substrate transport arm 250 with at least two degrees of freedom. As can be seen in FIGS. 3A, 3B, 3C and 3D each drive shaft 380S, 380AS, 380BS, 388 (where the collection of drive shafts forms a drive spindle) of the drive sections 300A, 300B, 300C, 300D is coaxial with the shoulder axis SX of the substrate transport arm 250, 250A, 250B coupled thereto. In one aspect, the substrate transport arm 250 includes three degrees of freedom while in other aspects the substrate transport arm has four or more degrees of freedom. A first end of the forearm 250FA is rotatably coupled to a second end 250UAE2 the upper arm 250UA at pivot joint (e.g. elbow joint) EX. A first end of the at least one end effector 250E is rotatably coupled to a second end of the forearm 250FA at pivot joint (e.g. wrist joint) WX where the second end of the end effector 250E includes the substrate holder 250E for holding the substrate S. Here the substrate transport arm 250 is articulate to transport the substrate S, held by the at least one substrate holder 250EH, in and out of the transport chamber 210 through the end and side substrate transport openings 260A, 260B, 270A1-270A6, 270B1-270B6 so that the end effector 250E is common to each of the end and side substrate transport openings 260A, 260B, 270A1-270A6, 270B1-270B6.

Referring also to FIGS. 3A, 3B, 3C, 3D in one aspect the transport apparatus 245 includes at least one drive section 300A, 300B, 300C, 300D and at least one transport arm portion having the at least one transport arm 250, 250A, 250B. The at least one transport arm 250, 250A, 250B may be coupled to the drive shafts of the drive sections 300A-300D in any suitable manner at any suitable connection CNX so that the rotation of the drive shafts effect movement of the at least one transport arm 250, 250A, 250B as described herein. In one aspect, the at least one transport arm 250, 250A, 250B may be interchangeable with a number of different interchangeable transport arms 250, 250A, 250B so as to be swapped at the connection CNX with the drive section, where each of the interchangeable transport arms 250, 250A, 250B have different droop characteristics and a corresponding droop distance register associated therewith that describes the arm droop distance of the associated transport arm 250, 250A, 250B so that the drive section may compensate for the droop using a compensating arm motion in the Z direction in a manner substantially similar to that described in, for example, U.S. provisional patent application No. 62/450,818 filed on Jan. 26, 2017 and entitled “Method and Apparatus for Substrate Transport Apparatus Position Compensation”, the disclosure of which is incorporated herein by reference in its entirety.

The at least one drive section 300A, 300B, 300C, 300D is mounted to any suitable frame 200F of the processing apparatus 200, such as to the frame 200F2 of the core module 200M2. In one aspect, the at least one drive section 300A, 300B, 300C may include a common drive section that includes a frame 300F that houses one or more of a Z axis drive 370 and a rotational drive section 382. An interior 300FI of the frame 300F may be sealed in any suitable manner as will be described below. In one aspect the Z axis drive 370 may be any suitable drive configured to move the at least one transport arm 250, 250A, 250B along the Z axis. In one aspect, the Z axis drive may be a screw type drive but in other aspects the drive may be any suitable linear drive such as a linear actuator, piezo motor, etc. The rotational drive section 382 may be configured as any suitable drive section such as, for example, a harmonic drive section. For example, the rotational drive section 382 may include any suitable number of coaxially arranged harmonic drive motors 380, such as can be seen in FIG. 3A where the drive section 382 includes three coaxially arranged harmonic drive motors 380, 380A, 380B. In other aspects the drives of drive section 382 may be located side-by-side and/or in a coaxial arrangement. In one aspect the rotational drive section 382 may include any suitable number of harmonic drive motors 380, 380A, 380B corresponding to, for example, any suitable number of drive shafts 380S, 380AS, 380BS in the coaxial drive system. The harmonic drive motor 380 may have high capacity output bearings such that the component pieces of a ferrofluidic seal 376, 377, are centered and supported at least in part by the harmonic drive motor 380 with sufficient stability and clearance during desired rotation T and extension R movements of the transport apparatus 245. It is noted that the ferrofluidic seal 376, 377 may include several parts that form a substantially concentric coaxial seal as will be described below. In this example the rotational drive section 382 includes a housing 381 that houses one or more drive motor 380 which may be substantially similar to that described in U.S. Pat. Nos. 6,845,250; 5,899,658; 5,813,823; and 5,720,590, the disclosures of which are incorporated by reference herein in their entireties. The ferrofluidic seal 376, 377 can be toleranced to seal each drive shaft 380S, 380AS, 380BS in the drive shaft assembly. In one aspect a ferrofluidic seal may not be provided. For example, the drive section 382 may include drives having stators that are substantially sealed from the environment in which the transport arms operate while the rotors and drive shafts share the environment in which the arms operate. Suitable examples, of drive sections that do not have ferrofluidic seals and may be employed in the aspects of the disclosed embodiment include the MagnaTran® 7 and MagnaTran® 8 robot drive sections from Brooks Automation, Inc. which may have a sealed can arrangement as will be described below. It is noted that drive shaft(s) 380S, 380AS, 380BS may also have a hollow construction (e.g. has a hole running longitudinally along a center of the drive shaft) to allow for the passage of wires or any other suitable items through the drive assembly for connection to, for example, another drive section as described in U.S. patent application Ser. No. 15/110,130 filed on Jul. 7, 2016 and published as US 2016/0325440 on Nov. 10, 2016, the disclosure of which is incorporated herein by reference in its entirety, any suitable position encoders, controllers, and/or the at least one transport arm 250, 250A, 250B, mounted to the drive 300A, 300B, 300C. As may be realized, each of the drive motors of drive section 300A, 300B, 300C may include any suitable encoders configured to detect a position of the respective motor for determining a position of the end effector 250E, 250E1, 250E2 of each transport arm 250, 250A, 250B.

In one aspect the housing 381 may be mounted to a carriage which is coupled to the Z axis drive 370 such that the Z axis drive 370 moves the carriage (and the housing 381 located thereon) along the Z axis. As may be realized, to seal the controlled atmosphere in which the at least one transport arm 250, 250A, 250B operates from an interior of the drive 300A, 300B, 300C (which may operate in an atmospheric pressure ATM environment) may include one or more of the ferrofluidic seal 376, 377 and a bellows seal. The bellows seal may have one end coupled to the carriage and another end coupled to any suitable portion of the frame 300FI so that the interior 300FI of the frame 300F is isolated from the controlled atmosphere in which the at least one transport arm 250, 250A, 250B operates.

In other aspects, a drive having stators that are sealed from the atmosphere in which the transport arms operate without a ferrofluidic seal, such as the MagnaTran® 7 and MagnaTran® 8 robot drive sections from Brooks Automation, Inc., may be provided on the carriage. For example, referring also to FIGS. 3B, 3C and 3D the rotational drive section 382 is configured so that the motor stators are sealed from the environment in which the robot arms operate while the motor rotors share the environment in which the robot arms operate.

FIG. 3B illustrates a coaxial drive having a first drive motor 380′ and a second drive motor 380A′. The first drive motor 380′ has a stator 380S′ and rotor 380R′ where the rotor 380R′ is coupled to drive shaft 380S. A can seal 380CS may be positioned between the stator 380S′ and rotor 380R′ and be connected to the housing 381 in any suitable manner so as to seal the stator 380S′ from the environment in which the robot arms operate. Similarly the motor 380A′ includes a stator 380AS' and rotor 380AR′ where the rotor 380AR′ is coupled to drive shaft 380AS. A can seal 380ACS may be disposed between the stator 380AS' and rotor 380AR′. The can seal 380ACS may be connected to the housing 381 in any suitable manner so as to seal the stator 380AS' from the environment in which the robot arms operate. As may be realized any suitable encoder/sensors 368A, 368B may be provided for determining a position of the drive shaft (and the arm(s) which the drive shaft(s) operates).

Referring to FIG. 3C a tri-axial rotational drive section 382 is illustrated. The tri-axial rotational drive section may be substantially similar to the coaxial drive section described above with respect to FIG. 3B however, in this aspect there are three motors 380′, 380A′, 380B′, each having a rotor 380R′, 380AR′, 380BR′ coupled to a respective drive shaft 380A, 380AS, 380BS. Each motor also includes a respective stator 380S′, 380AS′, 380BS' sealed from the atmosphere in which the robot arm(s) operate by a respective can seal 380SC, 380ACS, 380BCS. As may be realized any suitable encoders/sensors may be provided as described above with respect to FIG. 3C for determining a position of the drive shaft (and the arm(s) which the drive shaft(s) operates). Referring also to FIG. 3D, a drive 300D having a multi-axial rotational drive section 382 substantially similar to the tri-axial rotational drive section described above is illustrated having four drive shafts 380S, 380AS, 380BS, 388 and four respective motors 380′, 380A′, 380B′, 388M where the motor 388M includes a stator 388S, a rotor 388R and a can seal 388CS substantially similar to those described above. In one aspect, the four degree of freedom (not including a Z axis drive) drive 300D may be provided such as when the substrate transport arm, such as substrate transport arm 250B, is provided with fast swap end effectors where each end effector is independently rotatable relative to the other end effector(s). In one aspect, the three degree of freedom (not including a Z axis drive) drive 300C may be provided such as when the substrate transport arm, such as substrate transport arm 250B, is provided with fast swap end effectors that are differentially coupled as described above. As may be realized, in one aspect the drive shafts of the motors illustrated in FIGS. 3B, 3C and 3D may not allow for wire feed-through while in other aspects any suitable seals may be provided so that wires may be passed through, for example, hollow drive shafts of the motors illustrated in FIGS. 3B, 3C and 3D.

In one aspect, referring to FIGS. 2A, 2G and 2H, to compensate for arm droop (e.g. in addition to or in lieu of the compensating Z movement effected by the droop register described above) and/or to alleviate any bending moments exerted on the at least one drive section 300A, 300B, 300C, 300D due to the weight of the substrate transport arm 250, the first end 250UAE1 of the upper arm 250UA includes a balance ballast weight member 247 (shown in the figures schematically in a representative configuration for illustrative purposes) that extends from the pivot axis SX in an substantially opposite direction from an extension direction of the substrate transport arm, and with a configuration and weight defined based on balance of substrate transport arm droop moment on the pivot axis SX (e.g. on the drive spindle), and/or on fit within the compact footprint FP of the substrate transport arm 250. In one aspect, the ballast weight member 247 is fixedly mounted to a frame (such as a frame 250UAF of the upper arm 250UA) of the substrate transport arm 250 at a fixed location relative to the pivot axis SX as illustrated in FIG. 2G; while in other aspects, the ballast weight member 247 is movably mounted to the frame (such as a frame 250UAF of the upper arm 250UA) of the substrate transport arm 250 so as to be disposed at different locations, on the frame, towards and away (e.g. in direction 296 along the longitudinal axis LAX of the upper arm 250UA) from the pivot axis SX. In other aspects, the ballast weight member 247 may be mounted to any suitable portion of the substrate transport apparatus 245, such as independent of the transport arm links 250UA, 250FA, 250E, 250E1, 250E2. For example, the ballast weight member 247 may be fixedly or movably mounted to the frame or housing of the drive section 300A, 300B, 300C, 300D in any suitable manner such as, for example, by mounting the ballast weight member 247 to any one or more of the drive shafts or by mounting the ballast weight member 247 to a pivot shaft 247PA that is mounted to, for example, one of the drive shafts 380S, 380AS, 380BS, 388 of the drive section as illustrated in FIG. 21. In this example the pivot shaft 247PA is illustrated as being mounted to the drive shaft 280S in common with, but independently of the upper arm 250UA but as noted above, the pivot shaft 247PA may be mounted to any one of the drive shafts 380S, 380AS, 380BS, 388 of the drive section 300A, 300B, 300C, 300D.

In one aspect, the ballast weight member 247 is an active weight that moves relative to the frame (such as a frame 250UAF of the upper arm 250UA), away and towards the pivot axis SX in direction 296, in complement with extension and retraction of the substrate transport arm 250. For example, as the substrate transport arm 250 extends the ballast weight member 247 moves in direction 296 away from the shoulder axis SX and as the substrate transport arm 250 is retracted the ballast weight member 247 moves in direction 296 towards the shoulder axis SX. In one aspect, the ballast weight member 247 is moved relative to the substrate transport arm frame (such as a frame 250UAF of the upper arm 250UA) by at least one drive axis of the drive section 300A, 300B, 300C, 300D operably coupled to the substrate transport arm 250 and effecting articulation of the substrate transport arm 250 in any suitable manner. For example, the ballast weight member 247 may be mounted within the upper arm 250UA (or within the pivot shaft 247PA) on any suitable slide 247SL that is actuated by the drive section 300A, 300B, 300C, 300D in any suitable manner (such as through a band and pulley drive or any other suitable drive transmission). In one aspect, the at least one drive axis of the drive section 300A, 300B, 300C, 300D effects the movement of the ballast weight member 247, in direction 296, away and towards the pivot axis and effects extension and retraction of the substrate transport arm 250 so that the at least one drive axis is a common drive axis for motion of the ballast weight member 246 and extension and retraction of the substrate transport arm 250. For example, referring also to FIGS. 3A-3D, the outer drive shaft 380S may be coupled to the upper arm 250UA for rotating the upper arm 250UA about the shoulder axis SX. The middle drive shaft 380AS may be coupled to the forearm 250FA (such as through the band and pulley arrangement described herein) for rotating the forearm 250FA about the elbow axis EX. The inner drive shaft(s) 380BS, 388 may be coupled to the end effector(s) 250E, 250E1, 250E2 (such as through the band and pulley arrangement described herein) for rotating the end effector(s) 250E, 250E1, 250E2 about the wrist axis WX. The middle drive shaft 380AS may also be coupled to the ballast weight member 246 in any suitable manner, such as through a band and pulley arrangement that includes the shoulder pulley 410 and another pulley 412 disposed on the upper arm 250UA opposite the elbow pulley 411 relative to the shoulder axis SX. Bands 400A′, 400B′ may connect the pulleys 410, 412, and the ballast weight member 246 may be coupled to one of the bands 400A′, 400B′ in any suitable manner so as to move in direction 296 along any suitable linear slide 247SL. As may be realized, the pulley size ratio between pulley 410 and pulley 411 may be different than the pulley size ratio between pulley 410 and pulley 412 so that the movement of the ballast weight member 246 is calibrated to arm extension/retraction (e.g. the shoulder pulley 410 may include a first diameter to which the bands 400A, 400B are coupled and a second diameter to which bands 400A′, 400B′ are coupled, where the first and second diameters correspond to a respective one of the pulleys 411, 412). In other aspects, the ballast weight member 246 may be coupled to any suitable drive shaft 380S, 380AS, 380BS, 388 of the drive section 300A, 300B, 300C, 300D in common with any one of the upper arm 250UA, forearm 250FA and end effector 250E, 250E1, 250E2 in any suitable manner so that the ballast weight member 246 moves in direction 296.

Referring to FIG. 2G, the ballast weight member 247 has a ballast weight portion 247A, 247B, 247C that is selectable from a number of different interchangeable ballast weight portions 247A, 247B, 247C. In one aspect, selection of the interchangeable ballast weight portion 247A, 247B, 247C depends on the length L to width W aspect ratio of the substrate transport chamber 210. In other aspects, selection of the interchangeable ballast weight portion 247A, 247B, 247C may also depend on the type (e.g. single substrate holder end effectors such as end effectors 250E, 250E2 or side by side substrate holder end effectors such as end effector 250E1) or a number of end effectors 250E, 250E1, 250E2 included in the substrate transport arm 250. As an example, the ballast weight portion 247A, 247B, 247C selected for a transport chamber 210 configured with six side openings (as illustrated in, e.g., FIG. 2A) may weigh more than the ballast weight portion 247A, 247B, 247C selected for a transport chamber 210 configured with four side openings (as illustrated in, e.g., FIG. 9A). Similarly the ballast weight portion 247A, 247B, 247C selected for a transport chamber 210 configured with four side openings (as illustrated in, e.g., FIG. 9A) may weigh more than the ballast weight portion 247A, 247B, 247C selected for a transport chamber 210 configured with two side openings (as illustrated in, e.g., FIG. 11). In one aspect, where the substrate transport chamber 210 has a length L to width W aspect ratio of 1:1 no ballast may be provided (e.g. the ballast weight portion substantially does not add any counter weight to the substrate transport arm 250). As may be realized, the ballast weight portions 247A, 247B, 247C may be added or removed from the substrate transport arm 250 as needed depending, for example, on the aspect ratio of the substrate transport chamber 210 and/or the end effector(s) included in the substrate transport arm 250.

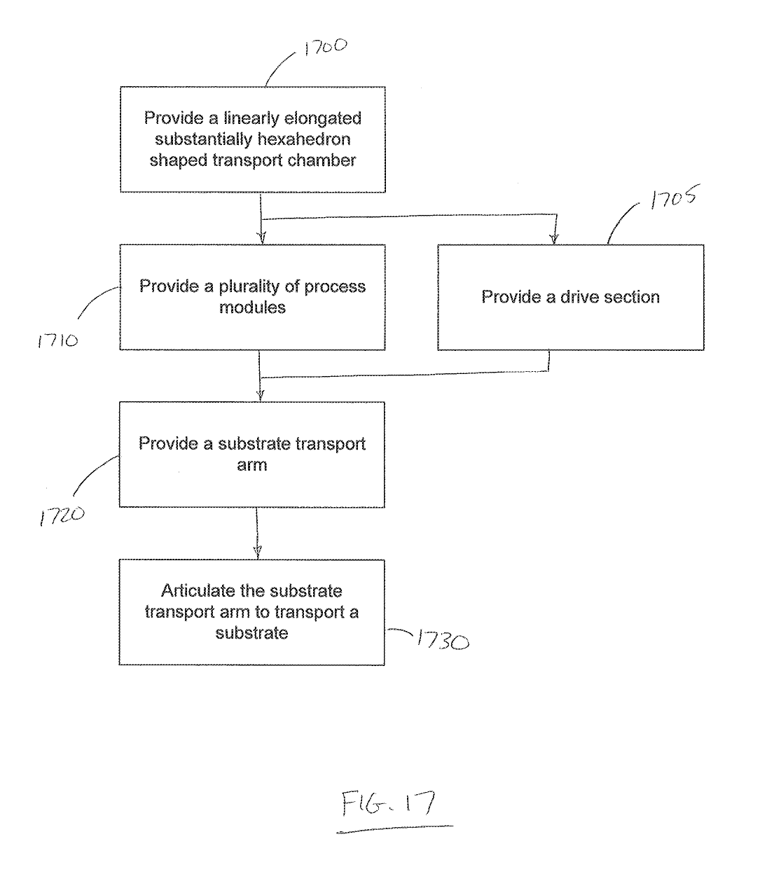

Referring now to FIGS. 2A, 2G, 2H and 13A-17, exemplary operations of the substrate processing tool 200 will be described. In one aspect, the substrate transport chamber 210 is provided (FIG. 17, Block 1700) and the plurality of process modules PM are linearly arrayed along at least one of the sides 210S1, 210S2 of the substrate transport chamber (FIG. 17, Block 1710) as described above. In one aspect, the process modules PM and/or load locks LL1, LL2 are also arrayed on the end walls 210E1, 210E2 of the substrate transport chamber 210. In one aspect, the drive section 300A, 300B, 300C, 300D, is provided and connected to the substrate transport chamber 210 (FIG. 17, Block 1705), where the drive section includes at least two degrees of freedom and each drive shaft 380S, 380AS, 380BS, 388 of the drive section 300A, 300B, 300C, 300D rotates about a common axis (such as the shoulder axis SX) with the other drive shafts 380S, 380AS, 380BS, 388 of the drive section 300A, 300B, 300C, 300D. In one aspect, the substrate transport arm 250 is provided (FIG. 17, Block 1720) and is pivotally mounted within the substrate transport chamber 210 so that a pivot axis (e.g. shoulder axis SX) of the transport arm is mounted fixed relative to the substrate transport chamber 210 as described above. As also described above, in one aspect, the shoulder axis SX of the transport arm 250 is a common axis with the drive shafts 380S, 380AS, 380BS, 388 of the drive section 300A, 300B, 300C, 300D.

In one aspect, the substrate transport arm 250 is articulated to transport the substrate (FIG. 17, Block 1730), held by the at least one substrate holder 250EH of the end effector 250E, 250E1, 250E2, in and out of the substrate transport chamber 210 through the end and side substrate transport openings 260A, 260B, 270A1-270A6, 270B1-270B6 so that the end effector 250E, 250E1, 250E2 is common to each of the end and side substrate transport openings 260A, 260B, 270A1-270A6, 270B1-270B6. In one aspect, where the ballast weight member 247 is active, articulation of the arm includes moving the ballast weight member 247 in direction 296 depending on the extension of the substrate transport arm 250.

In one aspect, as described above, the axis of substrate holder motion 270A1X-270A6X, 270B1X-270B6X through the side substrate transport openings 270A1-270A6, 270B1-270B6 is substantially orthogonal to another axis of substrate holder motion 260AX, 260BX through the end substrate transport opening 260A, 260B of the at least one end wall 250E1, 250E2. As also noted above, some of the axes of motion, such as 270A1X, 270A6X, 270B1X, 270B6X, are adjacent the end walls 210E1, 210E2 of the substrate transport chamber 210. The articulation of the substrate transport arm 250 by the drive section 300A, 300B, 300C, 300D is such that the substrate transport arm 250 is provided with the mobility to turn the end effector 250E, 250E1, 250E2 around the substantially orthogonal corner defines by the axes of motion 260AX, 260BX and axes of motion 270A1X, 270A6X, 270B1X, 270B6X.

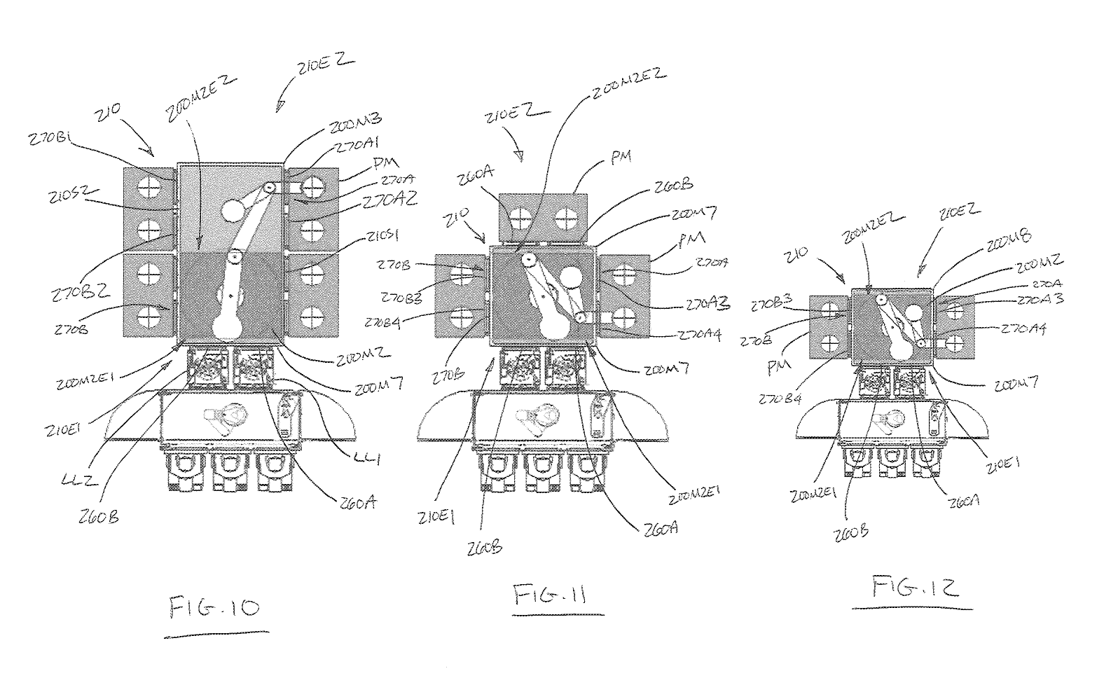

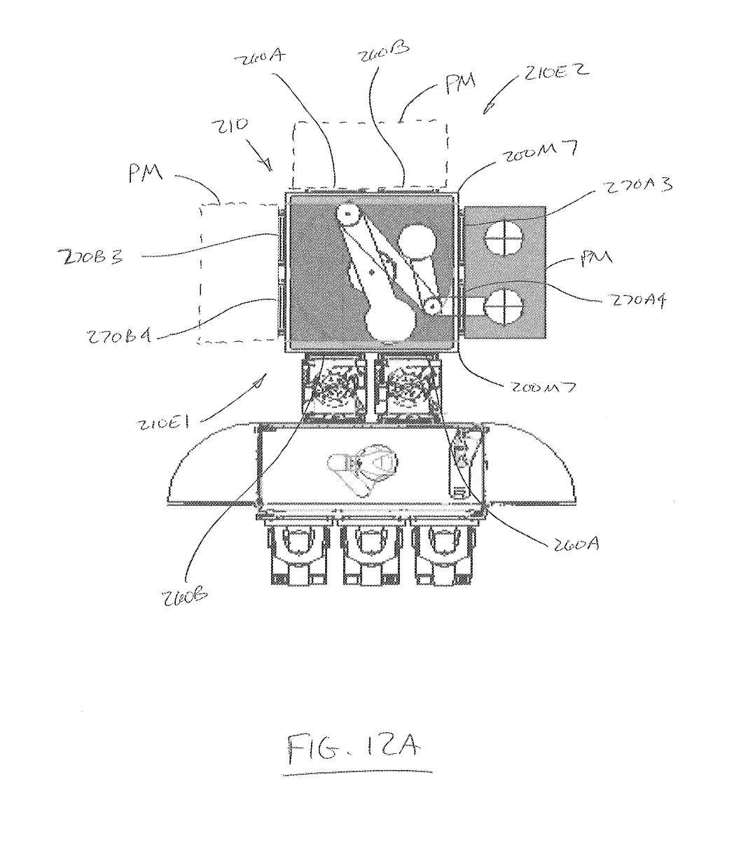

Referring to FIGS. 13A, 13B, an exemplary mobility of the end effector 250E, 250E1, 250E2 when the substrate transport arm 250 is retracted and extended into each of the end openings 260A, 260B is illustrated. Here, in the retracted configuration of the transport arm 250, with the shoulder axis SX being fixed relative to the substrate transport chamber 210 and having the drive shafts driving the transport arm being disposed coaxially with the shoulder axis SX, the end effector is provided with a range of motion 1300 of more than 270°, but less than 360°, of rotation relative to the wrist axis WX of the substrate transport arm 250 (see FIG. 13B). As the substrate transport arm 250 is extended so that the end effector 250E extends through end opening 260B, the end effector 250E (as well as end effector 250E2) maintains the range of motion 1300 of more than 270°, but less than 360°, of rotation relative to the wrist axis WX (see FIG. 13C). Similarly, as the substrate transport arm 250 is extended so that the end effector 250E extends through end opening 260A, the end effector 250E (as well as end effector 250E2) maintains the range of motion 1300 of more than 270°, but less than 360°, of rotation relative to the wrist axis WX (see FIG. 13D). As may be realized, the complete range of substrate transport arm 250 motion, throughout the reach and positions of arm motion is effected without restriction with the split band transmission 400 including independent articulation of the end effector 250E, 250E1, 250E2 for fast swap in contrast to conventional substrate processing systems, such as conventional processing tool 100 illustrated in FIG. 1, with conventional linearly elongated substrate transport chambers, and employing long arm links results in reduced mobility of the end effector with a band transmission, and in as the length of the transport chamber 114 is increased to accommodate more than three process modules (each process module having a single substrate holding station) on each side of the transport chamber 114, additional arm links are added to the substrate transport arm 150 where the additional links increase the moment acting on the substrate transport arm drive system by increasing the weight of the substrate transport arm. The increased weight of the substrate transport arm 150 as well as misalignment between the joints coupling the arm links together contribute to increasing droop or sagging of substrate transport arm 150 which may lead to decreased substrate placement and/or picking accuracy of the substrate transport arm 150. While the end openings 260A, 260B are illustrated on end wall 210E1 of the substrate transport chamber 210 it should be understood that extension of the end effector 250E, 250E1, 250E2 into end openings 260A, 260B on end wall 210E2 (such as in, e.g., FIG. 7) is substantially similar.

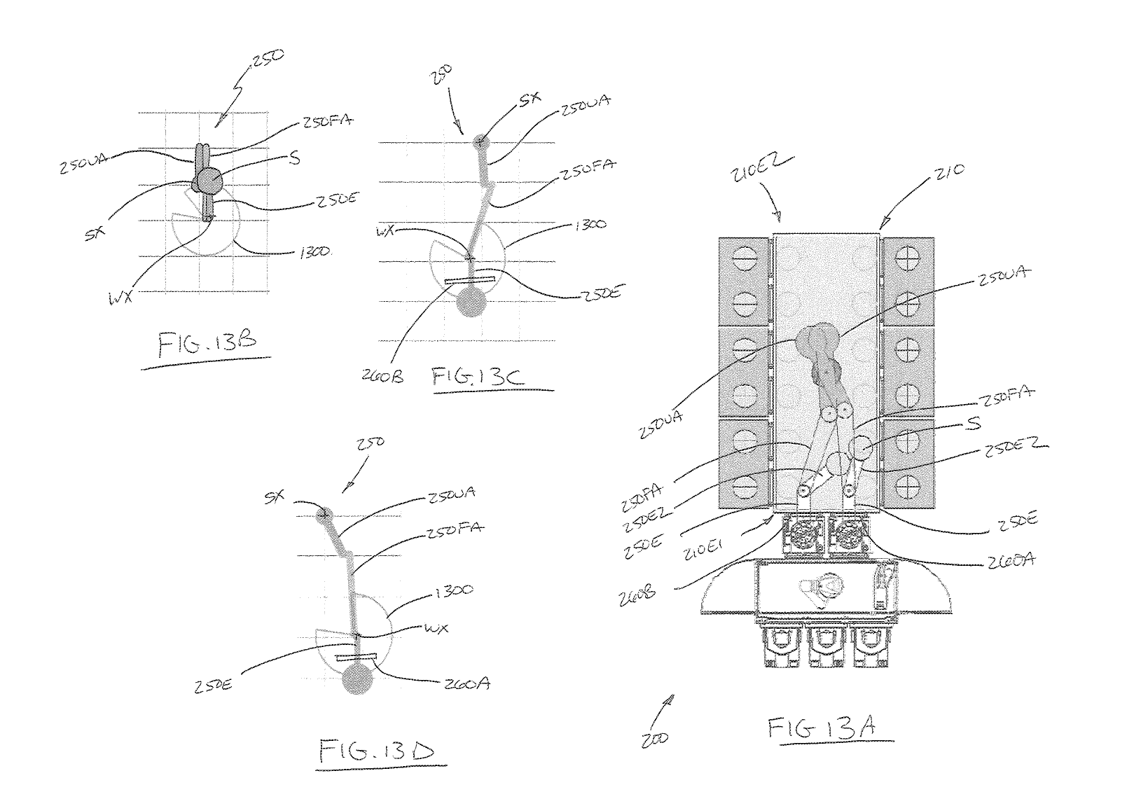

Referring to FIGS. 14A-14C, an exemplary mobility of the end effector 250E, 250E1, 250E2 when the substrate transport arm 250 is extended into each of the side openings 270A3, 270A4, 270B3, 270B4 (or the end openings 260A, 260B of a unitary aspect ratio transport chamber 210 as in, e.g., FIGS. 11 and 12) of the core module 200M2 is illustrated. Here, as the substrate transport arm 250 is extended so that the end effector 250E extends through side opening 270B3 or 270B4, the end effector 250E (as well as end effector 250E2) maintains the range of motion 1300 of more than 270°, but less than 360°, of rotation relative to the wrist axis WX (see FIG. 14B). Similarly, as the substrate transport arm 250 is extended so that the end effector 250E extends through side opening 270A3, 270A4, the end effector 250E (as well as end effector 250E2) maintains the range of motion 1300 of more than 270°, but less than 360°, of rotation relative to the wrist axis WX (see FIG. 14C). While side openings 270A3, 270B3 are illustrated in FIGS. 14B and 14C it should be understood that extension of the end effector 250E, 250E1, 250E2 into the side openings 270A4, 270B4 is substantially similar.

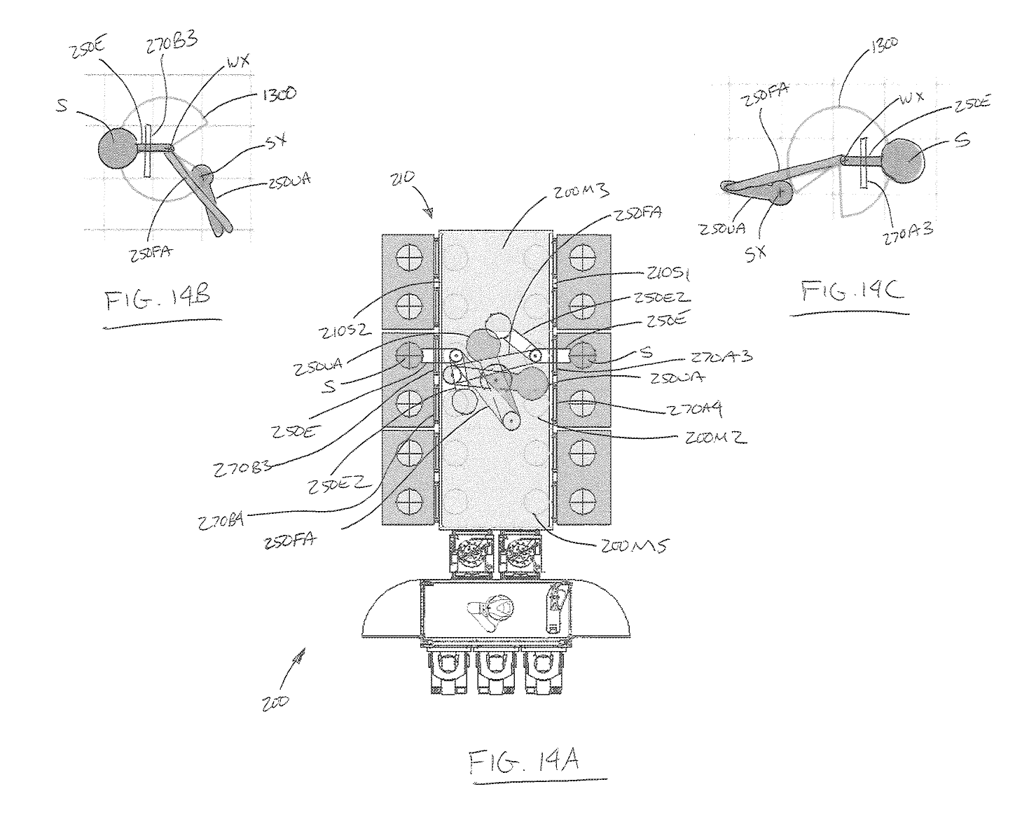

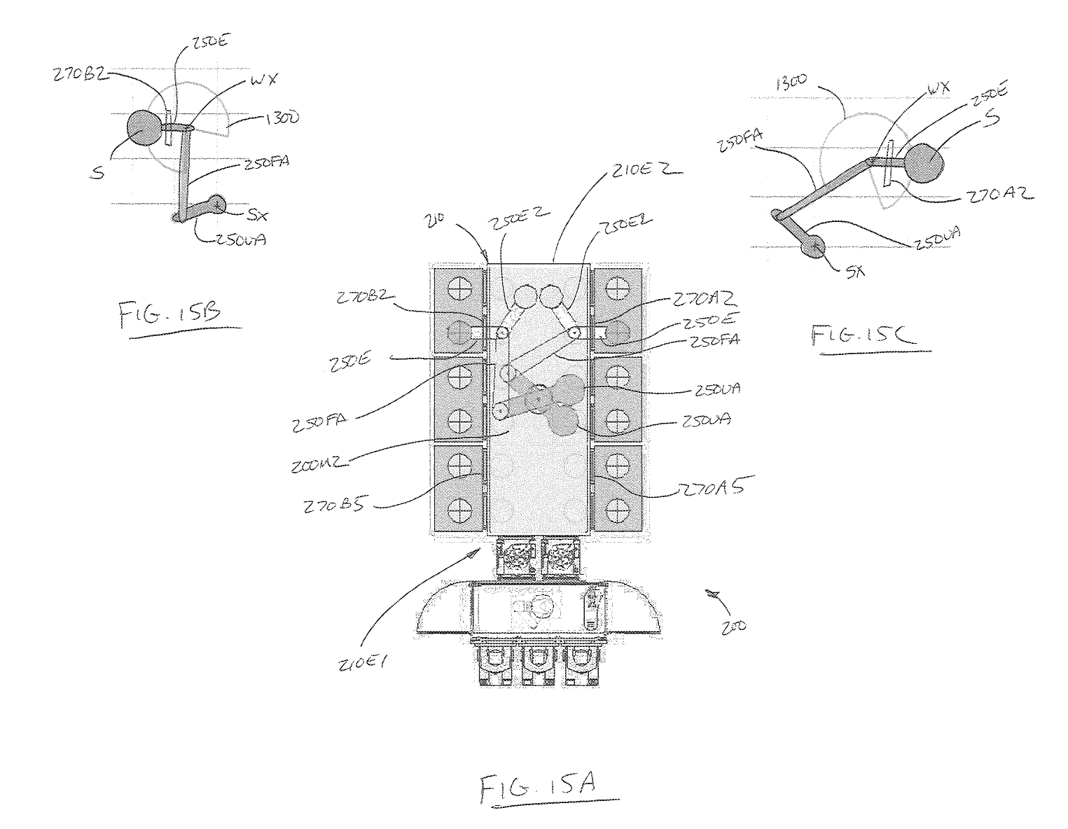

Referring to FIGS. 15A-15C, an exemplary mobility of the end effector 250E, 250E1, 250E2 when the substrate transport arm 250 is extended into each of the side openings 270A2, 270A5, 270B2, 270B5 (or the side openings 270A2, 270A5, 270B2, 270B5 adjacent the end walls 210E1, 210E2 of the transport chamber 210 having a length L to width W aspect ratio of 2:1 as in, e.g., FIGS. 9A and 9B) is illustrated. Here, as the substrate transport arm 250 is extended so that the end effector 250E extends through side opening 270B2, the end effector 250E (as well as end effector 250E2) maintains the range of motion 1300 of more than 270°, but less than 360°, of rotation relative to the wrist axis WX (see FIG. 15B). Similarly, as the substrate transport arm 250 is extended so that the end effector 250E extends through side opening 270A2 the end effector 250E (as well as end effector 250E2) maintains the range of motion 1300 of more than 270°, but less than 360°, of rotation relative to the wrist axis WX (see FIG. 15C). While side openings 270A2, 270B2 are illustrated in FIGS. 15B and 15C it should be understood that extension of the end effector 250E, 250E1, 250E2 into the side openings 270A5, 270B5 is substantially similar.

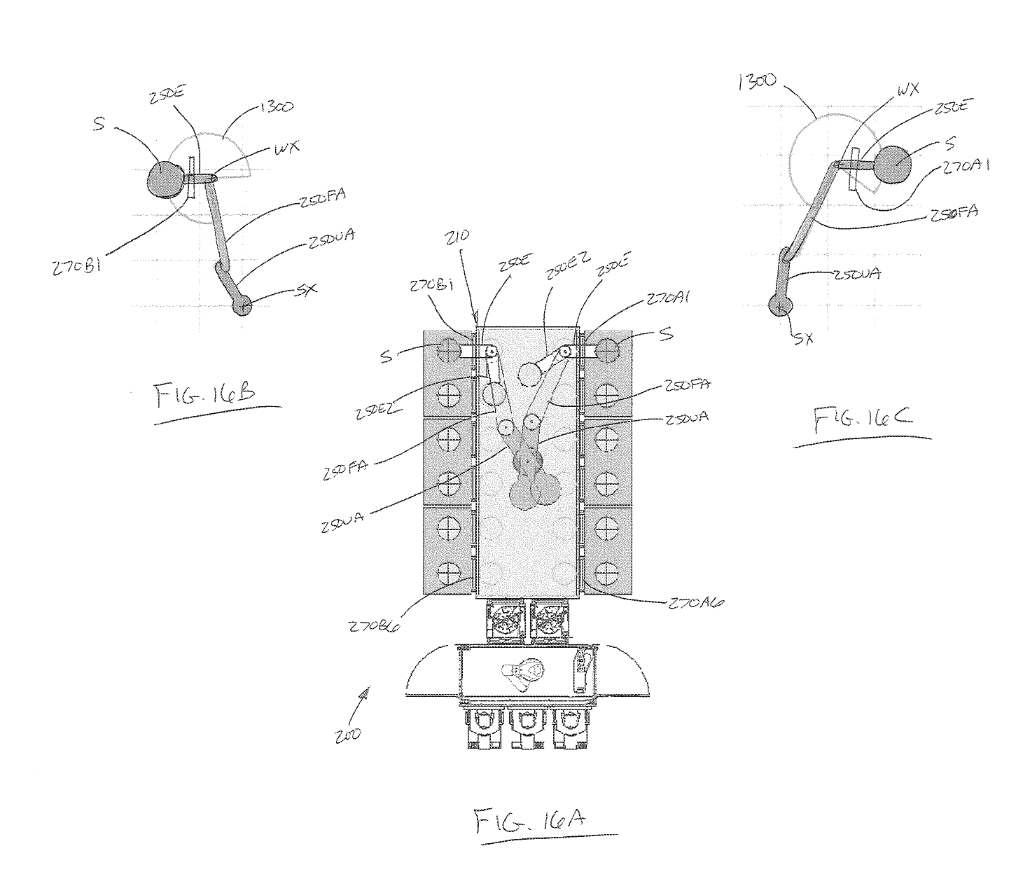

Referring to FIGS. 16A-16C, an exemplary mobility of the end effector 250E, 250E1, 250E2 when the substrate transport arm 250 is extended into each of the side openings 270A1, 270A6, 270B1, 270B6 adjacent the end walls 210E1, 210E2 of the transport chamber 210 having a length L to width W aspect ratio of 3:1 is illustrated. Here, as the substrate transport arm 250 is extended so that the end effector 250E extends through side opening 270B1, the end effector 250E (as well as end effector 250E2) maintains the range of motion 1300 of more than 270°, but less than 360°, of rotation relative to the wrist axis WX (see FIG. 16B). Similarly, as the substrate transport arm 250 is extended so that the end effector 250E extends through side opening 270A1 the end effector 250E (as well as end effector 250E2) maintains the range of motion 1300 of more than 270°, but less than 360°, of rotation relative to the wrist axis WX (see FIG. 16C). While side openings 270A1, 270B1 are illustrated in FIGS. 16B and 16C it should be understood that extension of the end effector 250E, 250E1, 250E2 into the side openings 270A6, 270B6 is substantially similar.

While FIGS. 13A-16C have been described with the substrate transport arm 250 including one or more of end effector 350E, 350E2 it should be understood that the range of motion 1300 of multiple substrate holder 250EH the end effector 250E2 is substantially similar to that described above. As may also be realized, the aspects of the disclosed embodiment provide the transport arm 250 with substantially unrestricted mobility, that includes a range of motion 1300 of the end effector 250E, 250E1, 250E2, that gives the substrate transport arm the capability to reach around the substantially orthogonal corners defined by the substantially orthogonal axes of motion 270AX1-270AX6, 270BX1-270BX6 and 260AX, 260BX, regardless of whether the axes of motion are adjacent an end wall 210E1, 210E2 of the substrate transport chamber 210. In one aspect, the range of motion 1300 of the end effector 250E, 250E1, 250E2 is provided with the shoulder axis SX being stationary or fixed relative to the substrate transport chamber 210, with the drive spindle of the drive section 300A, 300B, 300C, 300D being coaxial with the shoulder axis SX and/or with the drive band transmissions 400 (FIG. 4) driving rotation of the substrate transport arm 250 links (e.g. the forearm 250FA and end effectors 250E, 250E1, 250E2), where the drive band transmission provides tension on both sides of the pulleys 410, 411 regardless of the direction the pulleys are rotating (e.g. which increases the stiffness of the substrate transport arm 250). In one aspect, the range of motion 1300 of the end effector 250E, 250E1, 250E2 may be in excess of the range of motion for extending the end effector 250E, 250E1, 250E2 through an opening 270A1-270A6, 270B1-270B6, 260A, 260B along the respective axis of motion 270AX1-270AX6, 270BX1-270BX6, 260AX, 260BX (such as adjacent an end wall 210E1, 210E2 or anywhere between the end walls 210E1, 210E2) after rotating the end effector 250E, 250E1, 250E2 to compensate for the rotation of the upper arm 250UA and forearm 250FA drive axes (e.g. drive shafts 280A, 280AS) to effect extension of the substrate transport arm 250 while maintaining the end effector 250E, 250E1, 250E2 in a predetermined orientation (such as along the respective axis of motion 270AX1-270AX6, 270BX1-270BX6, 260AX, 260BX).

In accordance with one or more aspects of the disclosed embodiment a substrate processing apparatus comprises:

a linearly elongated substantially hexahedron shaped substrate transport chamber having linearly elongated sides of the hexahedron and at least one end wall of the hexahedron substantially orthogonal to the linearly elongated sides, the at least one end wall having an end substrate transport opening, at least one of the linearly elongated sides having a linear array of side substrate transport openings, each opening of the end and side substrate transport openings being arranged for transferring a substrate there through in and out of the substrate transport chamber;

a plurality of process modules linearly arrayed along the at least one of the linearly elongated sides and respectively communicating with the substrate transport chamber via corresponding side substrate transport openings; and

a substrate transport arm pivotally mounted within the substrate transport chamber so that a pivot axis of the substrate transport arm is mounted fixed relative to the substrate transport chamber, the substrate transport arm having a three link—three joint SCARA configuration, of which one link is an end effector with at least one substrate holder, that is articulate to transport the substrate, held by the at least one substrate holder, in and out of the substrate transport chamber through the end and side substrate transport openings so that the end effector is common to each of the end and side substrate transport openings;

wherein the hexahedron has a side length to width aspect ratio that is a high aspect ratio, and the width is compact with respect to a footprint of the substrate transport arm.

In accordance with one or more aspects of the disclosed embodiment the aspect ratio is greater than 2:1, and the substrate transport arm footprint is compact for a predetermined maximum reach of the substrate transport arm.

In accordance with one or more aspects of the disclosed embodiment the aspect ratio is about 3:1, and the substrate transport arm footprint is compact for a predetermined maximum reach of the substrate transport arm.

In accordance with one or more aspects of the disclosed embodiment the end wall is dimensioned to accept alongside, two side by side load lock or other process modules placed proximately adjacent each other on a common level and commonly facing the end wall.

In accordance with one or more aspects of the disclosed embodiment the SCARA arm has three degrees of freedom and unequal length links, and the pivot axis defines a shoulder joint of the SCARA arm.

In accordance with one or more aspects of the disclosed embodiment the process module linear array provides at least six process module substrate holding stations distributed along the at least one linearly elongated side at a substantially common level, and each of the substrate holding stations is accessed with the common end effector of the substrate transport arm through the corresponding side transport openings.

In accordance with one or more aspects of the disclosed embodiment comprising at least one load lock or other process module communicating with the substrate transport chamber via the end substrate transport opening.

In accordance with one or more aspects of the disclosed embodiment another of the linearly elongated sides opposite the at least one linearly elongated side of the substrate transport chamber has at least one other side substrate transport opening, and the substrate transport arm is configured to transport the substrate, held by the at least one substrate holder, in and out of the substrate transport chamber through the end, side, and other side substrate transport openings so that the end effector is common to each of the end, side and other substrate transport openings respectively disposed in the end wall, linearly elongated side and linearly elongated opposite side of the substrate transport chamber.

In accordance with one or more aspects of the disclosed embodiment the linearly elongated opposite side of the substrate transport chamber has more than one of the other side substrate transport openings, linearly arrayed along the opposite side, and wherein the end effector is common to each of the other side substrate transport openings.

In accordance with one or more aspects of the disclosed embodiment comprising a drive section connected to the substrate transport chamber and having a drive spindle comprising co-axial drive shafts operably coupled to the substrate transport arm and defining at least two degrees of freedom, effecting articulation of the substrate transport arm, and the drive spindle is located so its axis of rotation is substantially coincident with the pivot axis.

In accordance with one or more aspects of the disclosed embodiment the substrate transport arm has a balance ballast weight member disposed on the substrate transport arm so as to extend from the pivot axis in an substantially opposite direction from an extension direction of the substrate transport arm, and with a configuration and weight defined based on balance of substrate transport arm droop moment on the drive spindle.

In accordance with one or more aspects of the disclosed embodiment the substrate transport arm has a compact footprint for a predetermined maximum reach of the substrate transport arm, and the configuration and weight of the ballast weight member is further defined based on fit within the compact footprint of the substrate transport arm.

In accordance with one or more aspects of the disclosed embodiment the at least one substrate holder of the end effector comprises more than one substrate holders disposed on the end effector and arranged so that the end effector extends or retracts the more than one substrate holders substantially simultaneously through more than one of the linearly arrayed side substrate transport openings with a common end effector motion.

In accordance with one or more aspects of the disclosed embodiment the end effector is a first end effector, and the substrate transport arm has a second end effector dependent from a common forearm link of the substrate transport arm with the first end effector so that the first and second end effectors pivot relative to the forearm about a common rotation axis, wherein the second end effector is common to each of the end and side substrate transport openings.

In accordance with one or more aspects of the disclosed embodiment the first and second end effectors provide the substrate transport arm with a fast swap end effector that is common to each of the end and side substrate transport openings.

In accordance with one or more aspects of the disclosed embodiment the linearly elongated sides have a selectably variable length wherein the sides of the substrate transport chamber are selectable between different lengths and define a selectably variable configuration of the substrate transport chamber.

In accordance with one or more aspects of the disclosed embodiment the selectably variable configuration of the substrate transport chamber is selectable between a configuration where the side length to width aspect ratio varies from high aspect ratio to unity aspect ratio, and wherein the substrate transport arm is common to each selectable configuration of the substrate transport chamber.

In accordance with one or more aspects of the disclosed embodiment the substrate transport arm has a compact footprint for a predetermined maximum reach of the substrate transport arm, and has a balance ballast weight member disposed on the substrate transport arm so as to extend from the pivot axis in an substantially opposite direction from an extension direction of the substrate transport arm, and with a configuration and weight defined based on balance of substrate transport arm droop moment on the pivot axis, and on fit within the compact footprint of the substrate transport arm.

In accordance with one or more aspects of the disclosed embodiment the ballast weight member is fixedly mounted to a frame of the substrate transport arm at a fixed location relative to the pivot axis.

In accordance with one or more aspects of the disclosed embodiment the ballast weight member is movably mounted to a frame of the substrate transport arm so as to be disposed at different locations, on the frame, towards and away from the pivot axis.

In accordance with one or more aspects of the disclosed embodiment the ballast weight member is movably mounted to a frame of the substrate transport arm so as to move relative to the frame, away and towards the pivot axis, in complement with extension and retraction of the substrate transport arm.

In accordance with one or more aspects of the disclosed embodiment the ballast weight member is moved relative to the substrate transport arm frame by at least one drive axis of a drive section operably coupled to the substrate transport arm and effecting articulation of the substrate transport arm.

In accordance with one or more aspects of the disclosed embodiment the at least one drive axis effects the movement of the ballast weight member away and towards the pivot axis and effects extension and retraction of the substrate transport arm so that the at least one drive axis is a common drive axis for motion of the ballast weight member and extension and retraction of the substrate transport arm.

In accordance with one or more aspects of the disclosed embodiment the ballast weight member has a ballast weight portion that is selectable from a number of different interchangeable ballast weight portions and selection depends on the aspect ratio of the substrate transport chamber.

In accordance with one or more aspects of the disclosed embodiment the substrate transport arm includes a split band transmission system that effects articulation of the substrate transport arm.

In accordance with one or more aspects of the disclosed embodiment the substrate transport arm is a three degree of freedom transport arm.

In accordance with one or more aspects of the disclosed embodiment a substrate transport apparatus comprises:

a linearly elongated substantially hexahedron shaped substrate transport chamber having linearly elongated sides of the hexahedron and at least one end wall of the hexahedron having an end substrate transport opening, at least one of the linearly elongated sides of the hexahedron having a linear array of side substrate transport openings, each opening of the end and side substrate transport openings being arranged for transferring a substrate there through in and out of the substrate transport chamber;

a drive section, connected to the substrate transport chamber, and having a drive spindle, comprising co-axial drive shafts defining at least two degrees of freedom, rotating about a common axis; and

a substrate transport arm pivotally mounted within the substrate transport chamber so that a pivot axis of the substrate transport arm is mounted fixed relative to the substrate transport chamber substantially coincident with the common axis of the drive spindle, the substrate transport arm having a three link—three joint SCARA configuration, of which one link is an end effector with a substrate holder, that is operably coupled to the drive spindle so that the substrate transport arm is articulate with the at least two degrees of freedom, effected by the co-axial drive shafts, to transport the substrate on the substrate holder in and out of the substrate transport chamber through the end and side substrate transport openings;

wherein the substrate transport arm has a balance ballast weight member disposed on the substrate transport arm so as to extend from the common axis of the drive spindle in an substantially opposite direction from an extension direction of the substrate transport arm, and with a configuration and weight defined based on balance of substrate transport arm droop moment on the drive spindle.

In accordance with one or more aspects of the disclosed embodiment a side substrate transport opening, from the linear array of side substrate transport openings, disposed proximate another end of the hexahedron shaped substrate transport chamber opposite the at least one end wall, is oriented so that a corresponding axis of substrate holder motion through the side substrate transport opening proximate the opposite end is substantially orthogonal to another axis of substrate holder motion through the end substrate transport opening of the at least one end wall.

In accordance with one or more aspects of the disclosed embodiment the substrate transport arm is articulate to transport the substrate on the substrate holder in and out of the substrate transport chamber through the end and side substrate transport openings so that the end effector is common to each of the end and side substrate transport openings.

In accordance with one or more aspects of the disclosed embodiment each of the side substrate transport openings has corresponding axis of substrate holder motion through each side substrate transport opening, each of the axis of substrate holder motion of the linear array of side substrate transport openings extending substantially parallel with each other respectively through each substrate transport opening.

In accordance with one or more aspects of the disclosed embodiment the substrate transport arm has a compact footprint for a predetermined maximum reach of the substrate transport arm, and the hexahedron has a side length to width aspect ratio that is a high aspect ratio, and the width is compact with respect to the footprint of the substrate transport arm.

In accordance with one or more aspects of the disclosed embodiment the at least one end wall of the hexahedron is substantially orthogonal to the linearly elongated sides of the hexahedron.

In accordance with one or more aspects of the disclosed embodiment the substrate transport arm includes a split band transmission system that effects articulation of the substrate transport arm.

In accordance with one or more aspects of the disclosed embodiment the coaxial drive shafts provide the substrate transport arm with three degrees of freedom.

In accordance with one or more aspects of the disclosed embodiment a method comprises:

providing a linearly elongated substantially hexahedron shaped substrate transport chamber having linearly elongated sides of the hexahedron and at least one end wall of the hexahedron substantially orthogonal to the linearly elongated sides, the at least one end wall having an end substrate transport opening, at least one of the linearly elongated sides having a linear array of side substrate transport openings, each opening of the end and side substrate transport openings being arranged for transferring a substrate there through in and out of the substrate transport chamber;

providing a plurality of process modules linearly arrayed along the at least one of the linearly elongated sides and respectively communicating with the substrate transport chamber via corresponding side substrate transport openings;

providing a substrate transport arm pivotally mounted within the substrate transport chamber so that a pivot axis of the transport arm is mounted fixed relative to the substrate transport chamber, the substrate transport arm having a three link—three joint SCARA configuration, of which one link is an end effector with at least one substrate holder; and

articulating the substrate transport arm to transport the substrate, held by the at least one substrate holder, in and out of the substrate transport chamber through the end and side substrate transport openings so that the end effector is common to each of the end and side substrate transport openings;

wherein the hexahedron has a side length to width aspect ratio that is a high aspect ratio, and the width is compact with respect to a footprint of the substrate transport arm.

In accordance with one or more aspects of the disclosed embodiment the aspect ratio is greater than 2:1, and the substrate transport arm footprint is compact for a predetermined maximum reach of the substrate transport arm.

In accordance with one or more aspects of the disclosed embodiment the aspect ratio is about 3:1, and the substrate transport arm footprint is compact for a predetermined maximum reach of the substrate transport arm.

In accordance with one or more aspects of the disclosed embodiment the end wall is dimensioned to accept alongside, two side by side load lock or other process modules placed proximately adjacent each other on a common level and commonly facing the end wall.

In accordance with one or more aspects of the disclosed embodiment further comprising providing the SCARA arm with three degrees of freedom and unequal length links, where the pivot axis defines a shoulder joint of the SCARA arm.

In accordance with one or more aspects of the disclosed embodiment the process module linear array provides at least six process module substrate holding stations distributed along the at least one linearly elongated side at a substantially common level, the method further comprising accessing each of the substrate holding stations with the common end effector of the substrate transport arm through the corresponding side transport openings.

In accordance with one or more aspects of the disclosed embodiment at least one load lock or other process module communicates with the substrate transport chamber via the end substrate transport opening.

In accordance with one or more aspects of the disclosed embodiment another of the linearly elongated sides opposite the at least one linearly elongated side of the substrate transport chamber has at least one other side substrate transport opening, and the method further comprising transporting the substrate, held by the at least one substrate holder, with the substrate transport arm, in and out of the substrate transport chamber through the end, side, and other side substrate transport openings so that the end effector is common to each of the end, side and other substrate transport openings respectively disposed in the end wall, linearly elongated side and linearly elongated opposite side of the substrate transport chamber.

In accordance with one or more aspects of the disclosed embodiment the linearly elongated opposite side of the substrate transport chamber has more than one of the other side substrate transport openings, linearly arrayed along the opposite side, and wherein the end effector is common to each of the other side substrate transport openings.

In accordance with one or more aspects of the disclosed embodiment a drive section is connected to the substrate transport chamber and has a drive spindle comprising co-axial drive shafts operably coupled to the substrate transport arm and defining at least two degrees of freedom, the method further comprising effecting articulation of the substrate transport arm with the drive section where the drive spindle is located so its axis of rotation is substantially coincident with the pivot axis.

In accordance with one or more aspects of the disclosed embodiment further comprising providing the substrate transport arm with a balance ballast weight member disposed on the substrate transport arm so as to extend from the pivot axis in an substantially opposite direction from an extension direction of the substrate transport arm, and with a configuration and weight defined based on balance of substrate transport arm droop moment on the drive spindle.

In accordance with one or more aspects of the disclosed embodiment the substrate transport arm has a compact footprint for a predetermined maximum reach of the substrate transport arm, and the configuration and weight of the ballast weight member is further defined based on fit within the compact footprint of the substrate transport arm.

In accordance with one or more aspects of the disclosed embodiment the at least one substrate holder of the end effector comprises more than one substrate holders disposed on the end effector, the method further comprising extending or retracting the end effector so that the more than one substrate holders are substantially simultaneously extended or retracted through more than one of the linearly arrayed side substrate transport openings with a common end effector motion.

In accordance with one or more aspects of the disclosed embodiment the end effector is a first end effector, and the substrate transport arm has a second end effector dependent from a common forearm link of the substrate transport arm with the first end effector, the method further comprising pivoting the first and second end effectors relative to the forearm about a common rotation axis, wherein the second end effector is common to each of the end and side substrate transport openings.

In accordance with one or more aspects of the disclosed embodiment the first and second end effectors provide the substrate transport arm with a fast swap end effector that is common to each of the end and side substrate transport openings.

In accordance with one or more aspects of the disclosed embodiment the linearly elongated sides have a selectably variable length wherein, the method further comprising selecting the sides of the substrate transport chamber from sides having different lengths to define a selectably variable configuration of the substrate transport chamber.

In accordance with one or more aspects of the disclosed embodiment the selectably variable configuration of the substrate transport chamber is selectable between a configuration where the side length to width aspect ratio varies from high aspect ratio to unity aspect ratio, and wherein the substrate transport arm is common to each selectable configuration of the substrate transport chamber.

In accordance with one or more aspects of the disclosed embodiment the substrate transport arm has a compact footprint for a predetermined maximum reach of the substrate transport arm, the method further comprising providing the substrate transport arm with a balance ballast weight member disposed on the substrate transport arm so as to extend from the pivot axis in an substantially opposite direction from an extension direction of the substrate transport arm, and with a configuration and weight defined based on balance of substrate transport arm droop moment on the pivot axis, and on fit within the compact footprint of the substrate transport arm.

In accordance with one or more aspects of the disclosed embodiment the ballast weight member is fixedly mounted to a frame of the substrate transport arm at a fixed location relative to the pivot axis.

In accordance with one or more aspects of the disclosed embodiment further comprising moving the ballast weight member relative to a frame of the substrate transport arm so that the ballast weight member is disposed at different locations, on the frame, towards and away from the pivot axis.

In accordance with one or more aspects of the disclosed embodiment further comprising moving the ballast weight member relative to a frame of the substrate transport arm so that the ballast weight member moves relative to the frame, away and towards the pivot axis, in complement with extension and retraction of the substrate transport arm.

In accordance with one or more aspects of the disclosed embodiment the ballast weight member is moved relative to the substrate transport arm frame by at least one drive axis of a drive section operably coupled to the substrate transport arm and effecting articulation of the substrate transport arm.

In accordance with one or more aspects of the disclosed embodiment the at least one drive axis effects the movement of the ballast weight member away and towards the pivot axis and effects extension and retraction of the substrate transport arm so that the at least one drive axis is a common drive axis for motion of the ballast weight member and extension and retraction of the substrate transport arm.

In accordance with one or more aspects of the disclosed embodiment the method further comprising selecting a ballast weight portion of the ballast weight member from a number of different interchangeable ballast weight portions and the selection depends on the aspect ratio of the substrate transport chamber.

In accordance with one or more aspects of the disclosed embodiment further comprising effecting articulation of the substrate transport arm with a split band transmission system of the substrate transport arm.

In accordance with one or more aspects of the disclosed embodiment the substrate transport arm is a three degree of freedom transport arm.

In accordance with one or more aspects of the disclosed embodiment a method comprises:

providing a linearly elongated substantially hexahedron shaped substrate transport chamber having linearly elongated sides of the hexahedron and at least one end wall of the hexahedron having an end substrate transport opening, at least one of the linearly elongated sides of the hexahedron having a linear array of side substrate transport openings, each opening of the end and side substrate transport openings being arranged for transferring a substrate there through in and out of the substrate transport chamber;

providing a drive section, connected to the substrate transport chamber, and having a drive spindle, comprising co-axial drive shafts defining at least two degrees of freedom, rotating about a common axis;

providing a substrate transport arm pivotally mounted within the substrate transport chamber so that a pivot axis of the substrate transport arm is mounted fixed relative to the substrate transport chamber substantially coincident with the common axis of the drive spindle, the substrate transport arm having a three link—three joint SCARA configuration, of which one link is an end effector with a substrate holder; and

articulating the substrate transport arm, with the at least two degrees of freedom effected by the co-axial drive shafts of the drive spindle, to transport the substrate on the substrate holder in and out of the substrate transport chamber through the end and side substrate transport openings;

wherein the substrate transport arm has a balance ballast weight member disposed on the substrate transport arm so as to extend from the common axis of the drive spindle in an substantially opposite direction from an extension direction of the substrate transport arm, and with a configuration and weight defined based on balance of substrate transport arm droop moment on the drive spindle.

In accordance with one or more aspects of the disclosed embodiment a side substrate transport opening, from the linear array of side substrate transport openings, disposed proximate another end of the hexahedron shaped substrate transport chamber opposite the at least one end wall, is oriented so that a corresponding axis of substrate holder motion through the side substrate transport opening proximate the opposite end is substantially orthogonal to another axis of substrate holder motion through the end substrate transport opening of the at least one end wall.

In accordance with one or more aspects of the disclosed embodiment the substrate transport arm is articulate to transport the substrate on the substrate holder in and out of the substrate transport chamber through the end and side substrate transport openings so that the end effector is common to each of the end and side substrate transport openings.

In accordance with one or more aspects of the disclosed embodiment each of the side substrate transport openings has corresponding axis of substrate holder motion through each side substrate transport opening, each of the axis of substrate holder motion of the linear array of side substrate transport openings extending substantially parallel with each other respectively through each substrate transport opening.

In accordance with one or more aspects of the disclosed embodiment the substrate transport arm has a compact footprint for a predetermined maximum reach of the substrate transport arm, and the hexahedron has a side length to width aspect ratio that is a high aspect ratio, and the width is compact with respect to the footprint of the substrate transport arm.

In accordance with one or more aspects of the disclosed embodiment the at least one end wall of the hexahedron is substantially orthogonal to the linearly elongated sides of the hexahedron.

In accordance with one or more aspects of the disclosed embodiment further comprising effecting articulation of the substrate transport arm with a split band transmission system of the substrate transport arm.

In accordance with one or more aspects of the disclosed embodiment the substrate transport arm is a three degree of freedom transport arm.

It should be understood that the foregoing description is only illustrative of the aspects of the disclosed embodiment. Various alternatives and modifications can be devised by those skilled in the art without departing from the aspects of the disclosed embodiment. Accordingly, the aspects of the disclosed embodiment are intended to embrace all such alternatives, modifications and variances that fall within the scope of the appended claims. Further, the mere fact that different features are recited in mutually different dependent or independent claims does not indicate that a combination of these features cannot be advantageously used, such a combination remaining within the scope of the aspects of the invention.

What is claimed is:

1. A substrate processing apparatus comprising:
a linearly elongated substantially hexahedron shaped substrate transport chamber having linearly elongated sides of the hexahedron and at least one end wall of the hexahedron substantially orthogonal to the linearly elongated sides, the at least one end wall having an end substrate transport opening, at least one of the linearly elongated sides having a linear array of side substrate transport openings, each opening of the end and side substrate transport openings being arranged for transferring a substrate there through in and out of the substrate transport chamber;
the linear array of side substrate transport openings being arranged conformal with so as to couple to a plurality of process modules linearly arrayed along the at least one of the linearly elongated sides and respectively communicating with the substrate transport chamber via corresponding side substrate transport openings; and
a substrate transport arm pivotally mounted within the substrate transport chamber so that a pivot axis of the substrate transport arm is mounted fixed relative to the substrate transport chamber, the substrate transport arm having a three link—three joint SCARA configuration, of which one link is an end effector with at least one substrate holder, that is articulate to transport the substrate, held by the at least one substrate holder, in and out of the substrate transport chamber through the end and side substrate transport openings so that the end effector is common to each of the end and side substrate transport openings;
wherein the hexahedron has a side length to width aspect ratio that is a high aspect ratio, and the width is compact with respect to a footprint of the substrate transport arm.

2. The substrate processing apparatus of claim 1, wherein the aspect ratio is greater than 2:1, and the substrate transport arm footprint is compact for a predetermined maximum reach of the substrate transport arm.

3. The substrate processing apparatus of claim 1, wherein the aspect ratio is about 3:1, and the substrate transport arm footprint is compact for a predetermined maximum reach of the substrate transport arm.

4. The substrate processing apparatus of claim 1, wherein the end wall is dimensioned to accept alongside, two side by side load lock or other process modules placed proximately adjacent each other on a common level and commonly facing the end wall.

5. The substrate processing apparatus of claim 1, wherein the SCARA arm has three degrees of freedom and unequal length links, and the pivot axis defines a shoulder joint of the SCARA arm.

6. The substrate processing apparatus of claim 1, wherein the process module linear array provides at least six process module substrate holding stations distributed along the at least one linearly elongated side at a substantially common level, and each of the substrate holding stations is accessed with the common end effector of the substrate transport arm through the corresponding side transport openings.

7. The substrate processing apparatus of claim 1, further comprising at least one load lock or other process module communicating with the substrate transport chamber via the end substrate transport opening.

8. The substrate processing apparatus of claim 1, wherein another of the linearly elongated sides opposite the at least one linearly elongated side of the substrate transport chamber has at least one other side substrate transport opening, and the substrate transport arm is configured to transport the substrate, held by the at least one substrate holder, in and out of the substrate transport chamber through the end, side, and other side substrate transport openings so that the end effector is common to each of the end, side and other substrate transport openings respectively disposed in the end wall, linearly elongated side and linearly elongated opposite side of the substrate transport chamber.

9. The substrate processing apparatus of claim 8, wherein the linearly elongated opposite side of the substrate transport chamber has more than one of the other side substrate transport openings, linearly arrayed along the opposite side, and wherein the end effector is common to each of the other side substrate transport openings.

10. The substrate processing apparatus of claim 1, further comprising a drive section connected to the substrate transport chamber and having a drive spindle comprising co-axial drive shafts operably coupled to the substrate transport arm and defining at least two degrees of freedom, effecting articulation of the substrate transport arm, and the drive spindle is located so its axis of rotation is substantially coincident with the pivot axis.

11. The substrate processing apparatus of claim 1, wherein the at least one substrate holder of the end effector comprises more than one substrate holders disposed on the end effector and arranged so that the end effector extends or retracts the more than one substrate holders substantially simultaneously through more than one of the linearly arrayed side substrate transport openings with a common end effector motion.

12. The substrate processing apparatus of claim 1, wherein the end effector is a first end effector, and the substrate transport arm has a second end effector dependent from a common forearm link of the substrate transport arm with the first end effector so that the first and second end effectors pivot relative to the forearm about a common rotation axis, wherein the second end effector is common to each of the end and side substrate transport openings.

13. The substrate processing apparatus of claim 12, wherein the first and second end effectors provide the substrate transport arm with a fast swap end effector that is common to each of the end and side substrate transport openings.

14. The substrate processing apparatus of claim 1, wherein the linearly elongated sides have a selectably variable length wherein the sides of the substrate transport chamber are selectable between different lengths and define a selectably variable configuration of the substrate transport chamber.

15. The substrate processing apparatus of claim 14, wherein the selectably variable configuration of the substrate transport chamber is selectable between a configuration where the side length to width aspect ratio varies from high aspect ratio to unity aspect ratio, and wherein the substrate transport arm is common to each selectable configuration of the substrate transport chamber.

16. The substrate processing apparatus of claim 1, wherein the substrate transport arm has a compact footprint for a predetermined maximum reach of the substrate transport arm, and has a balance ballast weight member disposed on the substrate transport arm so as to extend from the pivot axis in an substantially opposite direction from an extension direction of the substrate transport arm, and with a configuration and weight defined based on balance of substrate transport arm droop moment on the pivot axis, and on fit within the compact footprint of the substrate transport arm.

17. The substrate processing apparatus of claim 16, wherein the ballast weight member is fixedly mounted to a frame of the substrate transport arm at a fixed location relative to the pivot axis.

18. The substrate processing apparatus of claim 16, wherein the ballast weight member is movably mounted to a frame of the substrate transport arm so as to be disposed at different locations, on the frame, towards and away from the pivot axis.

19. The substrate processing apparatus of claim 16, wherein the ballast weight member is movably mounted to a frame of the substrate transport arm so as to move relative to the frame, away and towards the pivot axis, in complement with extension and retraction of the substrate transport arm.

20. The substrate processing apparatus of claim 19, wherein the ballast weight member is moved relative to the substrate transport arm frame by at least one drive axis of a drive section operably coupled to the substrate transport arm and effecting articulation of the substrate transport arm.

21. The substrate processing apparatus of claim 20, wherein the at least one drive axis effects the movement of the ballast weight member away and towards the pivot axis and effects extension and retraction of the substrate transport arm so that the at least one drive axis is a common drive axis for motion of the ballast weight member and extension and retraction of the substrate transport arm.

22. The substrate processing apparatus of claim 18, wherein the ballast weight member has a ballast weight portion that is selectable from a number of different interchangeable ballast weight portions and selection depends on the aspect ratio of the substrate transport chamber.

23. The substrate processing apparatus of claim 10, wherein the substrate transport arm has a balance ballast weight member disposed on the substrate transport arm so as to extend from the pivot axis in an substantially opposite direction from an extension direction of the substrate transport arm, and with a configuration and weight defined based on balance of substrate transport arm droop moment on the drive spindle.

24. The substrate processing apparatus of claim 23, wherein the substrate transport arm has a compact footprint for a predetermined maximum reach of the substrate transport arm, and the configuration and weight of the ballast weight member is further defined based on fit within the compact footprint of the substrate transport arm.

25. The substrate processing apparatus of claim 1, wherein the substrate transport arm includes a split band transmission system that effects articulation of the substrate transport arm.

26. The substrate processing apparatus of claim 1, wherein the substrate transport arm is a three degree of freedom transport arm.

27. A substrate transport apparatus comprising:
a linearly elongated substantially hexahedron shaped substrate transport chamber having linearly elongated sides of the hexahedron and at least one end wall of the hexahedron having an end substrate transport opening, at least one of the linearly elongated sides of the hexahedron having a linear array of side substrate transport openings, each opening of the end and side substrate transport openings being arranged for transferring a substrate there through in and out of the substrate transport chamber;
a drive section, connected to the substrate transport chamber, and having a drive spindle, comprising co-axial drive shafts defining at least two degrees of freedom, rotating about a common axis; and
a substrate transport arm pivotally mounted within the substrate transport chamber so that a pivot axis of the substrate transport arm is mounted fixed relative to the substrate transport chamber substantially coincident with the common axis of the drive spindle, the substrate transport arm having a three link—three joint SCARA configuration, of which one link is an end effector with a substrate holder, that is operably coupled to the drive spindle so that the substrate transport arm is articulate with the at least two degrees of freedom, effected by the co-axial drive shafts, to transport the substrate on the substrate holder in and out of the substrate transport chamber through the end and side substrate transport openings;
wherein the substrate transport arm has a balance ballast weight member disposed on the substrate transport arm so as to extend from the common axis of the drive spindle in an substantially opposite direction from an extension direction of the substrate transport arm, and with a configuration and weight defined based on balance of substrate transport arm droop moment on the drive spindle.

28. The substrate transport apparatus of claim 27, wherein a side substrate transport opening, from the linear array of side substrate transport openings, disposed proximate another end of the hexahedron shaped substrate transport chamber opposite the at least one end wall, is oriented so that a corresponding axis of substrate holder motion through the side substrate transport opening proximate the opposite end is substantially orthogonal to another axis of substrate holder motion through the end substrate transport opening of the at least one end wall.

29. The substrate transport apparatus of claim 28, wherein the substrate transport arm is articulate to transport the substrate on the substrate holder in and out of the substrate transport chamber through the end and side substrate transport openings so that the end effector is common to each of the end and side substrate transport openings.

30. The substrate transport apparatus of claim 29, wherein each of the side substrate transport openings has corresponding axis of substrate holder motion through each side substrate transport opening, each of the axis of substrate holder motion of the linear array of side substrate transport openings extending substantially parallel with each other respectively through each substrate transport opening.

31. The substrate transport apparatus of claim 27, wherein the substrate transport arm has a compact footprint for a predetermined maximum reach of the substrate transport arm, and the hexahedron has a side length to width aspect ratio that is a high aspect ratio, and the width is compact with respect to the footprint of the substrate transport arm.

32. The substrate transport apparatus of claim 31, wherein the at least one end wall of the hexahedron is substantially orthogonal to the linearly elongated sides of the hexahedron.

33. The substrate transport apparatus of claim 27, wherein the substrate transport arm includes a split band transmission system that effects articulation of the substrate transport arm.

34. The substrate transport apparatus of claim 27, wherein the coaxial drive shafts provide the substrate transport arm with three degrees of freedom.

35. A method comprising:
providing a linearly elongated substantially hexahedron shaped substrate transport chamber having linearly elongated sides of the hexahedron and at least one end wall of the hexahedron substantially orthogonal to the linearly elongated sides, the at least one end wall having an end substrate transport opening, at least one of the linearly elongated sides having a linear array of side substrate transport openings, each opening of the end and side substrate transport openings being arranged for transferring a substrate there through in and out of the substrate transport chamber;
providing the linear array of side substrate transport openings an arrangement conformal with so as to couple to a plurality of process modules linearly arrayed along the at least one of the linearly elongated sides and respectively communicating with the substrate transport chamber via corresponding side substrate transport openings;
providing a substrate transport arm pivotally mounted within the substrate transport chamber so that a pivot axis of the transport arm is mounted fixed relative to the substrate transport chamber, the substrate transport arm having a three link—three joint SCARA configuration, of which one link is an end effector with at least one substrate holder; and
articulating the substrate transport arm to transport the substrate, held by the at least one substrate holder, in and out of the substrate transport chamber through the end and side substrate transport openings so that the end effector is common to each of the end and side substrate transport openings;
wherein the hexahedron has a side length to width aspect ratio that is a high aspect ratio, and the width is compact with respect to a footprint of the substrate transport arm.

36.-68. (canceled)
